(19) United States
(12) Patent Application Publication
(10) Pub. No.: US 2026/0029463 A1
(43) Pub. Date: Jan. 29, 2026

(54) COOLING SYSTEM USING A GASEOUS HEAT TRANSFER MEDIUM

(71) Applicant: Delta Design, Inc., Poway, CA (US)

(72) Inventors: Jerry Ihor Tustaniwskyj, San Juan Capistrano, CA (US); Anton Schuster, Grassau (DE)

(21) Appl. No.: 19/279,898

(22) Filed: Jul. 24, 2025

Related U.S. Application Data
(60) Provisional application No. 63/675,626, filed on Jul. 25, 2024.
(60) Provisional application No. 63/750,156, filed on Jan. 27, 2025.

(51) Int. Cl. G01R 31/28

(52) U.S. Cl. CPC G01R 31/2877

(57) ABSTRACT

An electronic testing system may use a gas phase heat transfer medium to cool components of the system and devices under test within the system. The heat transfer medium may be clean dry air, or other gas phase compounds.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119 (e) to U.S. Provisional Patent Application No. 63/675,626, filed Jul. 25, 2024, entitled “ELECTRICAL DEVICE TESTING SYSTEM USING A GASEOUS HEAT TRANSFER MEDIUM,” and U.S. Provisional Patent Application No. 63/750,156, filed Jan. 27, 2025, entitled “COOLING SYSTEM USING A GASEOUS HEAT TRANSFER MEDIUM.” The content of each of these applications is hereby expressly incorporated by reference in its entirety.

### BACKGROUND

### Technical Field

Embodiments of this disclosure relate to systems and methods for regulating temperature. More particularly, embodiments relate to a system for using clean dry air/compressed dry air or other gases as a thermal/heat transfer medium to control the temperature of electronic devices.

### Description of Related Technology

Temperature regulation systems are used to remove or add heat to an environment via the conduction of heat to or from the environment. Heat transfer is performed with a thermally conductive medium, generally a liquid with high thermal conductivity. Temperature regulation can be important for many industries, including the computer industry, where electronic systems give off tremendous amounts of heat during use.

Data centers are used in multiple industries to receive, store, and share data. Generally, a data center may have hundreds of servers mounted into racks and configured to process data. Each mounting rack may hold one or more servers, and each server may have many computer processing units (CPUs) and/or graphical processing units (GPUs) for performing one or more computational processes. CPUs and GPUs may give off a high volume of heat during use, which can accumulate and, if not mitigated, damage the CPUs and GPUs and servers. While others use cooling systems to regulate the temperature of these data servers, many such cooling systems use liquid medium to transfer heat away from the data servers. Should a leak occur in these systems, it may damage sensitive electronic components, including the CPUs and GPUs within the data servers or racks. Additionally, liquid medium capable of serving as a heat transfer medium and which do not pose equivalent risks associated with leaks tend to be expensive, flammable, and/or have environmentally related risks.

Automated Test Equipment (ATE) is used in the semiconductor industry to test semiconductor devices. Generally, the automated testing equipment is configured to receive a batch or “lot” of semiconductor devices for testing. The ATE conducts testing based on predetermined settings which are dependent upon the characteristics of each device input into the ATE for testing. During actual testing, various testing systems configured to manipulate the input device's operating conditions are applied to the input device and the result is recorded. For example, devices under test may be tested at particular temperatures to ensure that they perform adequately at a predetermined temperature, or within a predetermined temperature range. However, few liquid mediums useful to cool ATE are available which remain in liquid form throughout the required temperature range experienced during operation of a cooling system within such ATE.

In general, electronic devices to be tested are first placed into a tray which may be loaded into an ATE. Many types of trays are available. For example, JEDEC matrix trays may be used. These trays have standard dimensions of 12.7×5.35 inches (322.6×136 mm). Variations of these trays, such as low profile trays, with a thickness of approximately 0.25-inch (6.35 mm) can accommodate many standard electronic devices, including Ball Grid Array (BGA), Chip Scale Package (CSP), Quad Flat Package (QFP), Quad Flat No-Lead (QFN), Thin Small Outline Package (TSOP) and Small Outline Integrated Circuit (SOIC) type packaging, among many other types. High-profile JEDEC matrix trays with a height of 0.40 inches (10.16 mm) may be used to hold thicker electronic devices such as Plastic Leaded Chip Carrier (PLCC), Ceramic Quad Flat Package (CERQUAD), Pin Grid Arrays (PGA), and other modules and assemblies.

The electronic devices to be tested may be moved within the ATE by robotic equipment from the tray into various stations for running the various tests to confirm the functions of the device. During electrical testing, the electronic device is first connected to a contactor which includes a set of pins. These pins come into contact with the leads or solder balls of the device during electrical testing. Contact elements are commonly composed of a beryllium-copper base metal with gold-plating on the surface. During testing, each electronic device is inserted into the contactor for an electrical connection to the tester.

### SUMMARY OF THE INVENTION

In one aspect, a system for controlling temperature of an electronic device under test (DUT) comprises a closed circulation loop having pressurized therein a gas phase heat transfer medium at a pressure greater than an atmospheric pressure. The system includes a plunger configured to be in thermal communication with a first portion of the closed circulation loop and in further thermal communication with the DUT. The system additionally includes a heat exchanger configured to be in thermal communication with a second portion of the closed circulation loop.

In another aspect, an apparatus for testing an electronic device under test (DUT) comprises a testing station configured to receive a carrier assembly carrying the DUT and perform electrical testing on the DUT in the carrier assembly, wherein the carrier assembly comprises a carrier comprising a coupon to retain therein the DUT. The apparatus additionally includes a contactor assembly comprising a contactor configured to electrically and physically contact with the DUT at a first side of the coupon for sending and receiving testing signals. The apparatus also includes a closed circulation loop having pressurized therein a gas phase heat transfer medium at a pressure greater than an atmospheric pressure. The apparatus further includes a plunger configured to be in thermal communication with the DUT and with the closed circulation loop for controlling temperature of the DUT during testing.

In another aspect, an apparatus for testing an electronic device under test (DUT) comprises a testing station configured to receive the DUT and perform electrical testing therein using a contactor. The contactor is configured to electrically and physically contact with the DUT at a first side of the DUT for sending and receiving testing signals. The apparatus additionally includes a plunger configured to be in physical contact and thermal communication with the DUT at a second side for controlling temperature of the DUT during testing. The apparatus further includes a closed circulation loop having pressurized therein a gas phase heat transfer medium at a pressure greater than an atmospheric pressure in thermal communication with the plunger.

Another embodiment relates to a system for controlling temperature of an electronic device, wherein the electronic device is configured to be mounted within a mounting rack. The system comprises a closed circulation loop having pressurized therein a gas phase heat transfer medium at a pressure greater than an atmospheric pressure. The system includes a thermal block configured to be in thermal communication with a first portion of the closed circulation loop and in further thermal communication with the electronic device. The system includes a heat exchanger configured to be in thermal communication with a second portion of the closed circulation loop. In some embodiments, the electronic device comprises a computer server, wherein the computer server comprises at least a central processing unit (CPU) or a graphics processing unit (GPU).

Another embodiment relates to a method for controlling temperature of an electronic device under test (DUT). The method comprises receiving, by a system for controlling temperature of the DUT, a temperature from the DUT; determining, by the system, if the DUT temperature matches at a predetermined temperature target; and adjusting, by the system, power of a heating block based on the determination, wherein the system comprises: a closed circulation loop having pressurized therein a gas phase heat transfer medium at a pressure greater than an atmospheric pressure; a plunger in thermal communication with the DUT and further in thermal communication with the closed circulation loop, wherein the plunger comprises a thermal head comprising the heating block and a cooling block; and a heat exchanger configured to be in thermal communication with a second portion of the closed circulation loop.

### BRIEF DESCRIPTION OF THE DRAWINGS

Embodiments of this disclosure will be described, by way of non-limiting example, with reference to the accompanying drawings.

FIGS. 1A and 1B illustrate perspective front and side views of an electronic device testing system according to various embodiments.

FIG. 1C illustrates a top-down view of the electronic device testing system illustrated in FIGS. 1A and 1B according to various embodiments.

FIG. 1D illustrates a platter assembly for rotating carrier disks around stations of the electronic testing system according to embodiments.

FIG. 1E illustrates portions of a testing station according to various embodiments.

FIG. 1F illustrates a cross section of parts of a testing station according to various embodiments.

FIG. 1G illustrates an example socket layout kit according to various embodiments.

FIG. 1H illustrates another example socket layout kit according to various embodiments.

FIG. 1I illustrates a nest plunger according to various embodiments.

FIG. 2 is an example process of testing devices under test using an electronic device testing system according to various embodiments.

FIG. 3A is a schematic block diagram depicting an environment including an electrical device testing system that can have its temperature regulated with a clean or compressed dry air (CDA) system.

FIG. 3B is a schematic diagram depicting an experimental setup to measure the thermal properties of a thermal unit using the compressed dry air as a gas phase heat transfer medium.

FIG. 3C shows some simulation results about the thermal properties of a thermal unit using the compressed dry air as a gas phase heat transfer medium.

FIG. 3D shows some experimental results about the thermal properties of a thermal unit using the compressed dry air as a gas phase heat transfer medium.

FIG. 4 is a flow chart depicting a method for regulating temperature within an electrical device testing system using a clean or compressed dry air (CDA) system.

FIGS. 5A and 5B are schematic block diagrams depicting an environment for controlling temperature of electronic devices using a gas phase heat transfer medium.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

Generally described, aspects of the present disclosure relate to systems, apparatuses, and methods for controlling temperature by removing heat using a gas phase heat transfer medium. According to embodiments, a temperature control system can be integrated with an environment to transfer heat therefrom by using a gas phase heat transfer medium. The gas phase heat transfer medium can be a pressurized gas comprising compressed dry air (“CDA,” which may also be referred interchangeably as clean dry air). The pressurized gas may be at a pressure greater than the atmospheric pressure, e.g., about 1 atm. The gas phase heat transfer medium can be passed through a closed circulation loop, where a first portion of the closed circulation loop thermally communicates with a component, e.g., a plunger, that further thermally communicates with the object under thermal control, e.g., a DUT, and a second portion of the closed circulation loop thermally communicates with a heat exchanger. The gas phase heat transfer medium is chilled by passing through the second portion and thermal exchanging with the heat exchanger. For example, the gas phase heat transfer medium may run through a heat exchanger that is connected to a cooling system, such as a liquid nitrogen cooling system or a refrigeration system which includes one or more typical refrigeration condensing units. This allows the cooling system to absorb the heat from the gas phase heat transfer medium as it circles around the closed circulation loop.

In some embodiments, the object under thermal control can be a device under test (DUT). The systems, apparatuses, and methods of the present disclosure are implemented in a device testing system (which may also be referred to as DUT tester) and configured to remove heat from a DUT within the testing system.

In some embodiments, the object under thermal control can be parts of a data center, e.g., server blades or portions thereof. The gas phase heat transfer medium is configured to remove heat from data servers, which include central processing units and graphics processing units, or mounting racks.

### Temperature Control Systems for Integrated Circuit Device Testing Equipment

Some aspects of the present disclosure relate to systems and methods of maintaining the temperature of integrated circuit devices at a preset value or threshold as they are undergoing testing in a device testing system.

In one aspect, a system for controlling temperature of an electronic device under test (DUT) may comprise a closed circulation loop having pressurized therein a gas phase heat transfer medium at a pressure greater than an atmospheric pressure, a plunger configured to be in thermal communication with a first portion of the closed circulation loop and in further thermal communication with the DUT, and a heat exchanger configured to be in thermal communication with a second portion of the closed circulation loop. In one embodiment, the heat exchanger is in further thermal communication with a cooling system for transferring heat from the second portion of the closed circulation loop thereto.

In one embodiment, the plunger is configured to be in physical contact with the DUT. In one embodiment, the plunger comprises a network of cooling conduits forming a part of the closed circulation loop. In one embodiment, the plunger further comprises a heating block. In one embodiment, the heating block is configured to be closer to the DUT than the network of cooling conduits.

In one embodiment, in operation, the gas phase heat transfer medium is configured to be at a temperature lower than the DUT such that a net flow of heat occurs from the DUT to the gas phase heat transfer medium. In one embodiment, the gas phase heat transfer medium is at the pressure of about 7 bar to 10 bar. In one embodiment, the gas phase heat transfer medium comprises compressed dry air. In another embodiment, the gas phase heat transfer medium comprises a composition substantially different from ambient air. In another embodiment, the gas phase heat transfer medium comprises an inert gas. In another embodiment, the gas phase heat transfer medium does not include a hydrocarbon or a hydrofluorocarbon. In another embodiment, the gas phase heat transfer medium is not in a liquefied form within the closed circulation loop.

In one embodiment, the system further comprises a unidirectional pressure regulator connecting a pressurized gas reservoir to the closed circulation loop, the pressurized gas reservoir having the gas phase heat transfer medium at a higher pressure relative to that of the closed circulation loop. In one embodiment, the closed circulation loop comprises a pump configured to circulate the gas phase heat transfer medium around the closed circulation loop.

In some embodiments, the systems and methods described herein are designed to maintain a device under test (“DUT”) within a target temperature by modulating the temperature of a thermal head or plunger making contact with the DUT. The temperature may be modulated in the thermal head by providing a system which includes a closed circulation loop passing through internal channels of a cooling block thermally coupled to the thermal head or plunger. The system may also include a heating block in the thermal head which is also controllable and can be used to rapidly heat the thermal head to raise or lower the temperature of the thermal head in order to provide the correct temperature to the DUT. Thus, the system provides relatively consistent cooling power to the thermal head, and the heating block is used to control the temperature at the thermal head by powering on or off to raise and lower the thermal head temperature. For example, the test system may compare a temperature calculated from an output of a signal received from a DUT, or received from a thermal sensor located within the DUT, against a predetermined target temperature and accordingly raise or lower a temperature of the thermal head using the heating block as described below.

Further aspects of this disclosure relate to an automated testing equipment configured with temperature control capability as described herein, also called an “electronic device testing system” or “DUT Tester,” with improved reliability, efficiency and/or cost associated with testing electronic components. The electronic device testing system may provide automation for testing electronic devices or components. The electronic devices applied to the electronic device testing system can include, but are not limited to, semiconductor device components, including packaged and unpackaged integrated circuit (IC) dies, including monolithically integrated IC dies as well as bonded or stacked IC dies that include passive and/or active circuitry. Such dies can include integrated circuits, such as logic circuitry, volatile and nonvolatile memory circuitry, power delivery circuitry, photonic integrated circuitry, to name a few. The electronic devices that are being tested in the electronic testing system may be referred to as devices under test (“DUTs”).

Thus, an apparatus for testing an electronic device under test (DUT) comprises a testing station configured to receive the DUT and perform electrical testing therein using a contactor, which is configured to electrically and physically contact with the DUT at a first side of the DUT for sending and receiving testing signals, a plunger configured to be in physical contact and thermal communication with the DUT at a second side for controlling temperature of the DUT during testing, and a closed circulation loop having pressurized therein a gas phase heat transfer medium at a pressure greater than an atmospheric pressure in thermal communication with the plunger.

In one embodiment, the plunger is configured to be in thermal communication with a first portion of the closed circulation loop, and wherein the apparatus further comprises a heat exchanger in thermal communication with a second portion of the closed circulation loop.

In one embodiment, the heat exchanger is in further thermal communication with a cooling system for transferring heat from the second portion of the closed circulation loop thereto.

In one embodiment, in operation, the gas phase heat transfer medium is configured to be at a temperature lower than the DUT such that a net flow of heat occurs from the DUT to the gas phase heat transfer medium. In one embodiment, the gas phase heat transfer medium is at the pressure of about 7 bar to 10 bar. In one embodiment, the gas phase heat transfer medium comprises a composition substantially different from ambient air. In one embodiment, the gas phase heat transfer medium comprises an inert gas. In one embodiment, the gas phase heat transfer medium does not include a hydrocarbon or a hydrofluorocarbon. In one embodiment, the gas phase heat transfer medium is not in a liquefied form within the closed circulation loop.

Types of electronic device packages which may be tested within the electronic device testing systems described herein include Ball Grid Arrays (BGA), Chip Scale Packages (CSP), Quad Flat Packages (QFP), Quad Flat No-Leads (QFN), Thin Small Outline Packages (TSOP), Small Outline Integrated Circuit (SOIC), Plastic Leaded Chip Carrier (PLCC), Ceramic Quad Flat Package (CERQUAD), and Pin Grid Arrays (PGA). Other types of packages are also contemplated within embodiments of the invention.

Many challenges of designing electronic device testing systems arise from handling the IC packages, e.g., using vacuum handlers, as they are transferred and probed. One of the challenges is reducing the displacement of a DUT during operation of the testing equipment (sometimes referred to as “device out of pocket”), which is often caused in part due to handling of the DUTs. Another challenge is reducing DUTs being stuck within components of the testing equipment, such as handlers or contactors. Another challenge is keeping the DUTs at a temperature closer to the test temperature prior to testing the individual DUTs to improve throughput. Another challenge is keeping the testing environment substantially dry to reduce condensation on the DUTs that might occur when transported into the testing system from ambient temperature.

To address these and other needs, the disclosed electronic device testing systems are configured to transfer DUTs from a tray into a carrier assembly. The carrier assembly moves through a plurality of stations and through completion of the testing of the DUTs, without transferring the DUTs out of the carrier assembly. The DUTs are carried in the carrier assembly as the carrier assembly is moved from one station to another within the system. The DUTs are retained in the carrier assembly using a plurality of “coupons” that are attached to the carrier assembly but are allowed limited lateral and vertical movements and degrees of freedom while being carried, until the DUTs are tested. For example, the coupons may allow each DUT to have up to six degrees of freedom, including three independent linear degrees of freedom and three independent angular degrees of freedom, until the DUT is secured for testing. The six degrees of freedom also help the DUT properly align with components of the system, such as a contactor. The stations include an electronic testing station where the DUTs are tested in the carrier assembly without being removed from the carrier assembly or the coupons. In the electronic testing station, a contactor electrically contacts the DUTs retained in the carrier assembly to send and receive electrical signals. The temperature of the DUTs may also be actively controlled during testing using a thermal head having a plunger which contacts the DUTs on the opposite side of the DUT from the contactor. The thermal head/plunger may be equipped with an automatic temperature control (“ATC”) system including a heating block and a cooling block for maintaining a substantially constant DUT temperature during testing. In addition, the plunger may also be connected to a cooling system and incorporate a heater to help maintain the DUT at a predetermined temperature during testing.

Thus, an apparatus for testing an electronic device under test (DUT) may comprise a testing station configured to receive a carrier assembly carrying the DUT and perform electrical testing on the DUT in the carrier assembly, wherein the carrier assembly comprises a carrier comprising a coupon to retain therein the DUT, a contactor assembly comprising a contactor configured to electrically and physically contact with the DUT at a first side of the coupon for sending and receiving testing signals, a closed circulation loop having pressurized therein a gas phase heat transfer medium at a pressure greater than an atmospheric pressure; and a plunger configured to be in thermal communication with the DUT and with the closed circulation loop for controlling temperature of the DUT during testing.

In one embodiment, the plunger is in thermal communication with a first portion of the closed circulation loop, and wherein a second portion of the closed circulation loop is configured to be in thermal communication with a heat exchanger. In one embodiment, the heat exchanger is in further thermal communication with a cooling system for transferring heat from the second portion of the closed circulation loop thereto. In one embodiment, the plunger is configured to be in physical contact with the DUT at a second side of the coupon. In one embodiment, the plunger comprises a network of cooling conduits forming a part of the closed circulation loop. In one embodiment, the plunger further comprises a heating block. In one embodiment, the heating block is configured to be closer to the DUT than the network of cooling conduits.

In one embodiment, in operation, the gas phase heat transfer medium is configured to be at a temperature lower than the DUT such that a net flow of heat occurs from the DUT to the gas phase heat transfer medium. In one embodiment, the gas phase heat transfer medium is at the pressure of about 7 bar to 10 bar. In one embodiment, the gas phase heat transfer medium comprises compressed dry air. In one embodiment, the gas phase heat transfer medium comprises a composition substantially different from ambient air. In one embodiment, the gas phase heat transfer medium comprises an inert gas. In one embodiment, the gas phase heat transfer medium does not include a hydrocarbon or a hydrofluorocarbon. In one embodiment, the gas phase heat transfer medium is not in a liquefied form within the closed circulation loop.

In one embodiment, the apparatus further comprises a unidirectional pressure regulator connecting a pressurized gas reservoir to the closed circulation loop, the pressurized gas reservoir having the gas phase heat transfer medium at a higher pressure relative to that of the closed circulation loop. In one embodiment, the closed circulation loop comprises a pump, configured to circulate the gas phase heat transfer medium around the closed circulation loop.

The testing system may also include other stations through which the DUTs are transported in carrier assemblies including, for example, a soak up station and a soak down station preceding the testing station. To improve throughput, the DUTs may be brought and kept at a temperature closer to the testing temperature prior to testing. To reduce the lag time associated with bringing the DUTs closer to the testing temperature, the soak up station, the soak down station and the testing station are enclosed in a thermal chamber under a common temperature-controlled atmosphere. The carrier assemblies may be stacked into a stack and singulated from the stack in the soak up and soak down stations, respectively, prior to being tested. For example, a carrier assembly may be loaded into a soak up stack, raised to the top of the stack as other carrier assemblies are loaded, moved laterally into a soak down stack, and then lowered into position along the soak down stack until it can continue to the testing station. This movement creates a lag time allowing the carrier assemblies and DUTs to reach their target temperature before moving into the testing station.

The thermal chamber keeps the DUTs closer to the testing temperature by circulating temperature-controlled gas such as compressed dry air. The thermal chamber may also be held under a positive pressure (relative to local ambient pressure) of compressed dry air to minimize any condensation that may occur on the DUTs. In addition, an input station at which the untested DUTs are introduced into carrier assemblies, an output station from which the tested DUTs are unloaded, and a tray precising station (TPS), from which DUTs on a tray in a tray frame are pick-and-placed in the carrier assembly in the input or output station, may also be kept at a positive pressure (relative to local ambient pressure) of compressed dry air, which may be at room temperature, in a separate dry chamber to reduce any moisture that may enter into the thermal chamber.

In addition, the disclosed electronic testing systems are configured to transfer the carrier assemblies carrying the DUTs from one station to the next by rotating carrier retainer disks retaining the carriers in a circular pattern using a platter assembly. The carrier assemblies rotate about a vertical axis of the device testing system, without using robotic arms or handlers to move the carrier assemblies. Each carrier retainer disk may also rotate about its own central axis to compensate for the rotation about the vertical axis, such that the carrier assemblies remain substantially aligned in the same direction through completion of the testing. This process maintains each DUT within a carrier in the same position with the test system and helps reduce jostling and damage that may come from moving the DUTs within the test system during the transfer from station to station. This may also significantly reduce jams caused by displacements of the DUTs or DUTs being stuck on or within testing components or stations.

In addition, the disclosed electronic testing systems include a DUT tray input/output system for transferring untested DUTs onto the carrier assemblies in the testing chamber, and transferring tested DUTs out of the carrier assemblies and out of the testing chamber back to a tray, using a pick-and-place handler. In one embodiment, the system may use tray frames configured to mate with the trays to pick up and move the trays into and out of the system. The DUT tray input/output system may include as few as three motor drives configured to transfer the trays, held by the tray frames, into and out of the testing chamber. The DUTs within the trays may be monitored and identified using a vision monitoring system prior to being placed in the carrier assemblies for tracking. The tray frames may be made of an inflexible material, such as metal, so that when they mate with a tray, they can reduce any tray warpage and straighten and align the trays for pick and place precision movement. This may also help to further reduce displacement of DUTs from the trays due to tray warpage.

Thus, in one embodiment, the apparatus for testing an electronic device under test (DUT) may further comprise a plurality of stations including the testing station, wherein the carrier assembly rotates through the plurality of stations on a carrier retainer disk without being removed from the carrier retainer disk. In one embodiment, the apparatus may further comprise an input station, configured to receive the DUT from one or more tray stacks when the carrier assembly is temporarily at the input station to receive the DUT. In one embodiment, the apparatus may further comprise an output station, configured to receive the carrier assembly carrying the DUT and remove the DUT out of the carrier assembly and send it to the tray stacks. In one embodiment, the stations comprise one or more soak stations configured to receive the carrier assembly carrying the DUT and bring temperature of the DUT closer to a testing temperature. In one embodiment, at least the testing station is enclosed in a temperature-controlled thermal chamber. In another embodiment, the testing station and the one or more soak stations are enclosed within the temperature-controlled thermal chamber.

In some aspects, the electronic device testing system disclosed herein may intake DUTs that are to be tested, index the DUTs, test the DUTs, record the results of testing, and output the indexed and tested DUTs while reducing instances of DUT displacements. The disclosed electronic device testing system may increase DUT throughput, reduce testing stoppage, reduce repairs or other maintenance, and/or provide other benefits.

### Active Thermal Control Process

Some aspects of the present disclosure are also related to systems and methods to active thermal control (“ATC”), which may also be referred to as automatic temperature control. Applying ATC is configured to maintain a substantially constant temperature of DUT during testing.

When DUTs are using a high amount of electrical power during a test the DUT may rapidly increase in temperature. To maintain a DUT at a target temperature during these tests, the system can employ an active thermal control process. During this active thermal control process, the temperature of the device under test may be constantly monitored. For example, many DUTs include output pins or solder balls which report a signal related to the temperature of the DUT. The system may monitor this output from the DUT to determine the real-time or near real-time temperature of the DUT. When the detected temperature of the DUT increases or decreases during the testing process as compared to a target temperature, the system will increase or decrease the temperature of a heating block on the thermal head to maintain the device at the target temperature. For example, if the device draws an additional 10 watts of power and begins to heat up, the system may detect the additional heat and decrease an amount of power provided to the heating block. Because the system is constantly providing cooling power to the thermal head by circulating a cold gas, such as CDA, through the thermal head, reducing the heat generated by the heating block on the thermal head lowers the temperature of the thermal head and reduces the DUT's temperature. Decreasing power provided to a heating block can reduce a DUT's temperature by causing the heating block to generate less heat, which can cause a plunger physically coupled to the heating block and the DUT to become colder, resulting in the plunger absorbing more heat from the DUT during the test. Similarly, if the DUT is below a target temperature during a test process, the system may increase the temperature of the heating block to increase an amount of thermal energy generated by the heating block, which results in the thermal head or plunger physically coupled to the heating block becoming warmer.

### Heat/Thermal Transfer Medium

Gas has a comparably low thermal mass and thus, using gas as a heat transfer medium to cool the thermal head can require the gas to be compressed. This compression raises the gas's density and its thermal mass, enabling the gas to hold more thermal energy. In some embodiments, the system can hold gas within a range of 1-30 bars (or atmospheres). In some embodiments, the gas in the system may be pressurized within a range of 7-10 bars. In other embodiments, the gas in the system may be pressurized to be greater than 1, 2, 3, 4, 5, 6, 7, 8, 9, 10 or more bars, or a value in a range defined by any of these values.

In some embodiments, gas used as a heat transfer medium can be compressed dry air (“CDA”), which is a gas composition approximating that of general atmospheric composition. The gas may also be selected from helium, argon, nitrogen, neon, hydrofluoroether (HFE) or any other suitable gas which can be used as a thermal transfer medium.

The systems and methods described herein also relate to maintaining a desired gas pressure within a closed circulation loop by passively releasing pressurized gas stored within a gas reservoir if a sufficient pressure differential is achieved. In order to maintain the correct pressure of gas within the system, the system may include a reservoir of gas (“gas reservoir”). This reservoir can be connected to the system to supply additional pressurized gas when needed. The gas within the gas reservoir is advantageously kept at a pressure greater than the gas pressure within a corresponding closed circulation/cooling loop. This is because if the gas pressure within the gas reservoir were lower than the gas pressure inside the closed circulation loop, gas would flow from the loop and into the gas reservoir instead of from the gas reservoir to the loop. For gas to flow in a desired direction, the system preferably maintains a pressure gradient, with the desired direction of location flow having a lower fluid pressure.

In some embodiments, adding gas to a pressurized closed circulation/cooling loop from a gas reservoir uses a mechanism to selectively open the gas reservoir to the closed circulation/cooling loop. The mechanism can be a passive regulator. In some embodiments, the passive regulator contains a damper (a plate which blocks flow of fluid) and a spring which applies a specified amount of force on the plate. When a pressure gradient between a heat transfer medium within a closed circulation/cooling loop and the gas reservoir is too low, the force of the spring can be overpowered by the gas pressure, causing the plate to move in an orientation which allows gas to flow from the gas reservoir into the closed circulation/cooling loop, increasing the pressure within the closed circulation/cooling loop. Moving the gas phase heat transfer medium through the closed circulation/cooling loop can involve one or more compressors, valves, evaporators, heat transfer blocks, and related fans and blowers as would be within a typical cooling loop system.

### Temperature Control System for Data Center

Aspects of this disclosure relate to systems and methods of cooling an electronic device under load within a data center. The electronic devices within a data center may include data servers and their associated hardware, including, but not limited to computer processing units (CPUs) and/or graphical processing units (GPUs). Typical data centers employ cooling of their electronic systems due to the heat released by the components which generate heat during operations. In many circumstances, the electronic devices are configured to receive, store, and/or share data. The devices may be housed within a mounting rack configured to hold the electronic device.

To address these and other needs, according to embodiments, cooling systems within the data center may use a gas as a thermal/heat transfer medium to cool the electronic devices. In one embodiment, the gas is compressed dry air, although other gases such as helium, argon, neon, or hydrofluoroether (HFE) are also contemplated to be used as gas phase heat transfer mediums.

When electronic devices are under load (provided with electrical power) the electronic devices may rapidly increase in temperature, potentially leading to reduced performance or damage to the electronic devices. Many challenges of designing data servers arise from maintaining processors at a sufficiently low temperature to avoid performance or physical degradation due to excessive temperatures while carrying an electrical load. To maintain an electronic device at a sufficiently low temperature while under load, systems can employ cooling means to remove excess heat from the electronic device. However, some existing temperature regulation systems utilize liquid coolants which, although functional, can pose operational, environmental, health and cost risks. For example, microprocessors exposed to liquid coolants can be electronically damaged due to short circuits or other electrical malfunctions caused by leaks.

To address these and other needs, the disclosed data servers are integrated with a closed circulation loop with gas phase heat transfer medium therein, which is configured to transfer heat from the heat-generating electronic components within a data center to a secondary cooling system. The closed circulation loop may be connected to a cooling system to help maintain the electronic devices at a desired temperature.

Some embodiments of the systems and methods described herein are designed to remove heat from electronic devices by transferring the heat from the electronic device into a gas phase heat transfer medium circulating in the closed circulation loop. A thermal block can be in thermal communication with the electronic device and in further thermal communication with a first portion of a close circulation loop. The closed circulation loop has pressurized therein a gas phase heat transfer medium at a pressure greater than an atmospheric pressure, e.g., about 1 atm or about 1 bar. A heat exchanger can be in thermal communication with a second portion of the closed circulation loop. The electronic device may be mounted within a mounting rack.

In some embodiments, the thermal block may be positioned within close proximity to, e.g., in contact with, the electronic device and configured to pass cooling power via airflow across and/or through a heat transfer device, such as a radiator. In some embodiments, the thermal block may be a cooling block in direct thermal contact with the electronic device and configured to provide cooling power to the electronic device by conducting heat away from the electronic device. The closed circulation loop may maintain a substantially constant gas pressure and flow rate of the gas phase heat transfer medium, thereby providing relatively consistent cooling power to the electronic devices within a data center.

### Electronic Device Testing System

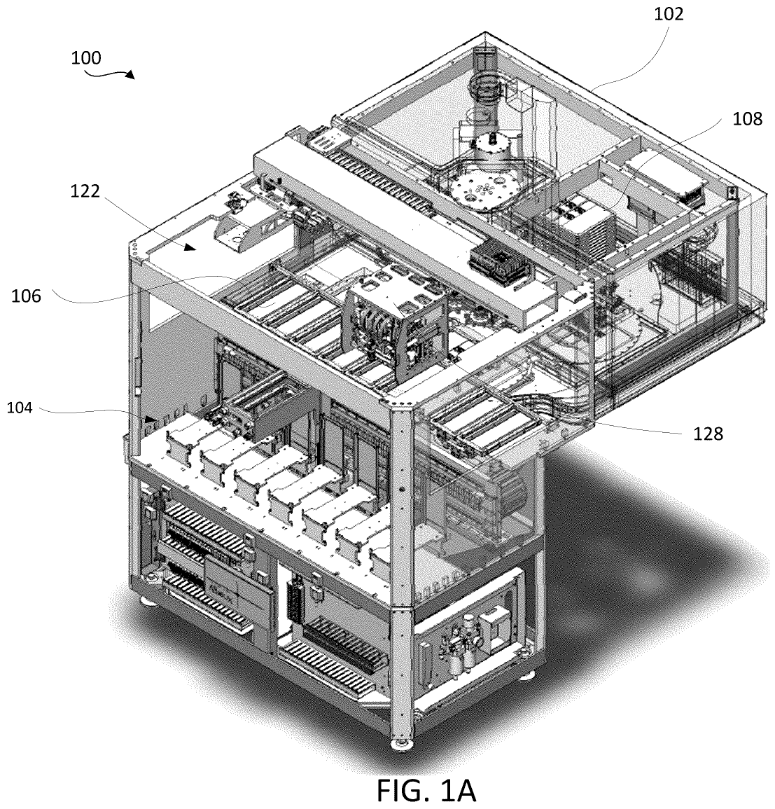

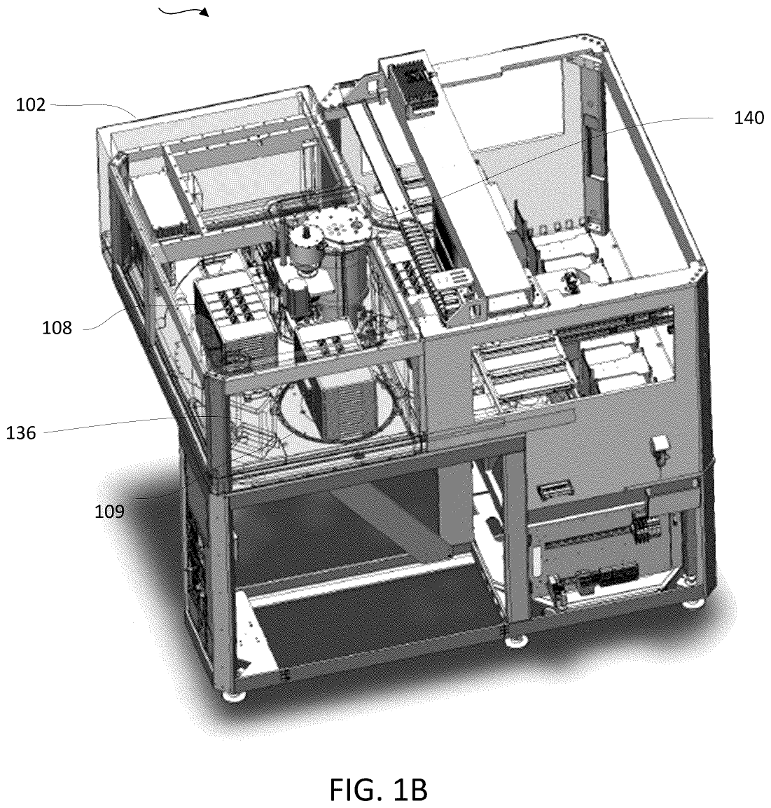

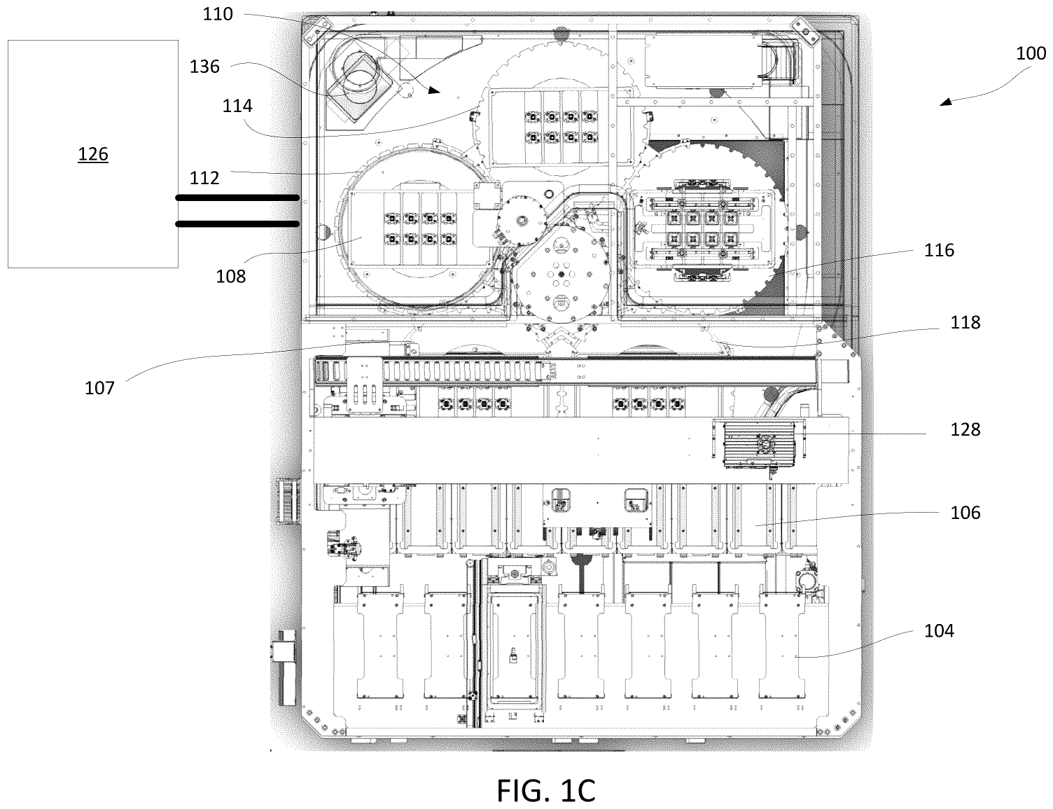

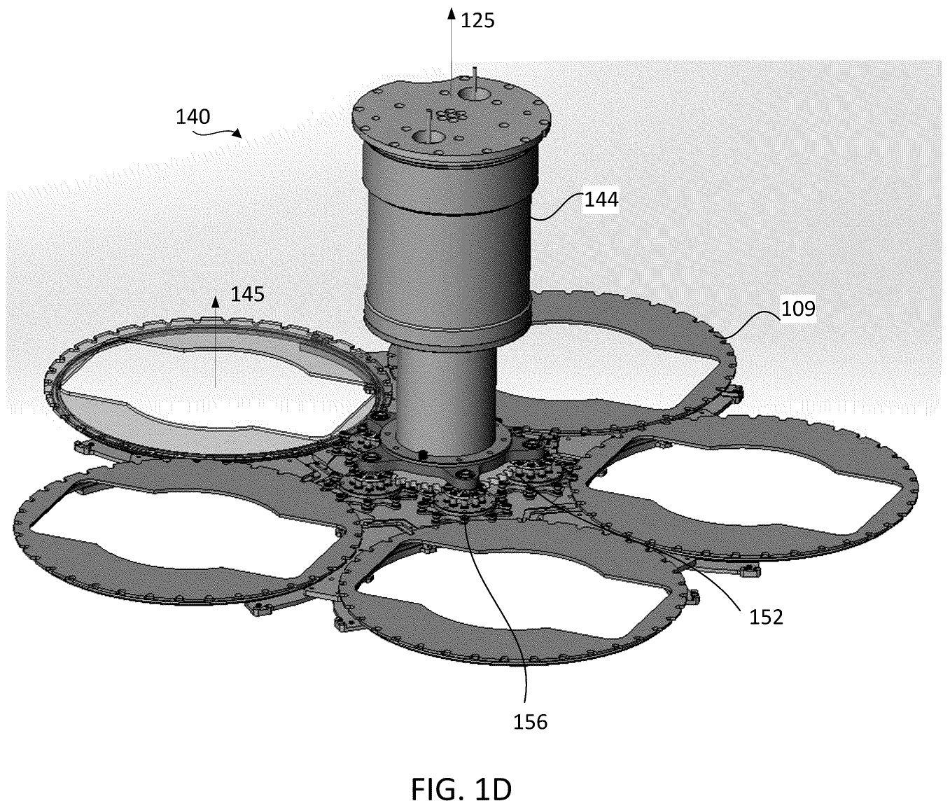

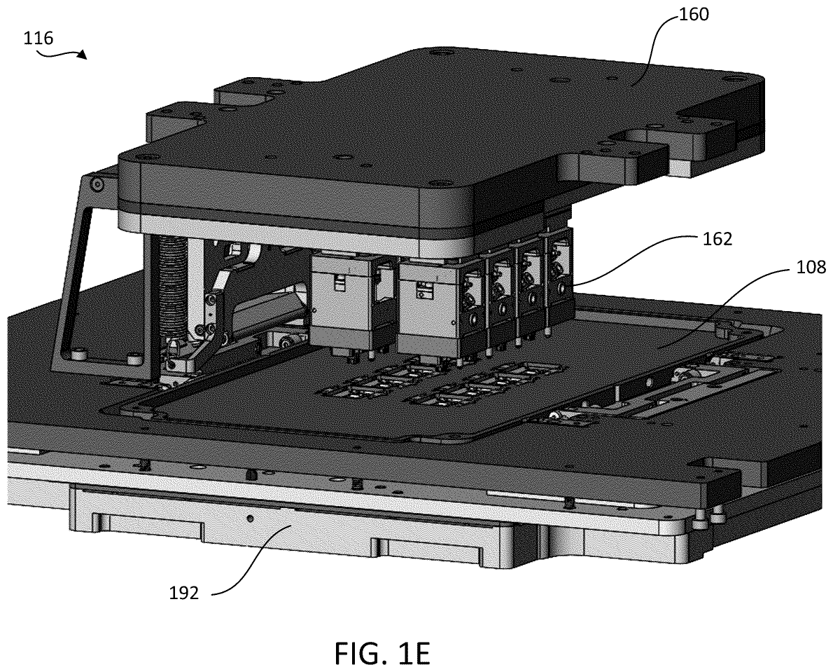

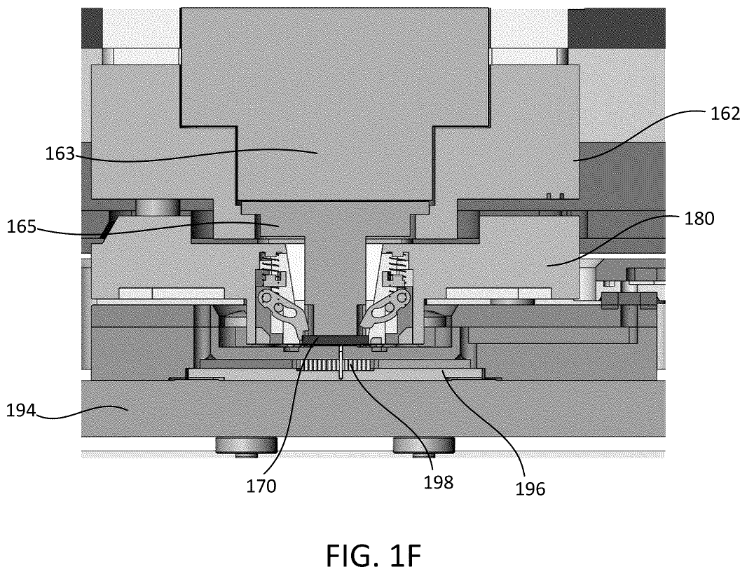

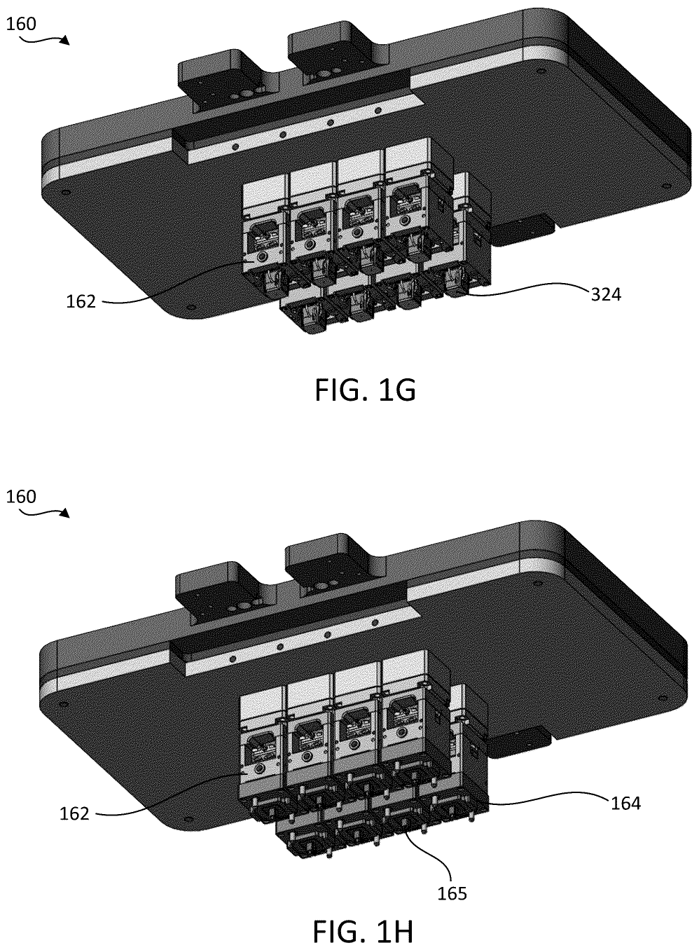

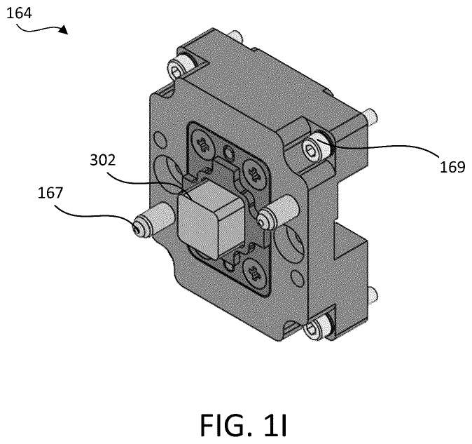

FIGS. 1A-1C illustrate an electronic device testing system 100, according to various embodiments. FIGS. 1A and 1B are perspective front and side views and FIG. 1C is a top-down view of the device testing system 100. In the illustrated embodiment, the electronic device testing system 100 includes tray stacks 104 (FIG. 1A, actual stacks not shown) an input station 107, carriers 108 (FIGS. 1A-1C), carrier retainer disks 109 (FIG. 1B), a thermal staging area 110 (FIG. 1C) with a soak up station 112 (FIG. 1C) and a soak down station 114 (FIG. 1C), a testing station 116 (FIG. 1C), and an output or sort station 118 (FIG. 1C). In the illustrated embodiment, the electronic device testing system 100 additionally includes a tray precising station (TPS) 106 (FIGS. 1A, 1C) from which DUTs in a tray are transferred into the input station 107 and out of the output station 118 using a pick-and-place (PnP) head 128 (FIGS. 1A, 1C). In the electronic testing system 100, as described above, the soak up station 112, the soak down station 114 and the testing station 116 may be in a thermal chamber 102 (FIGS. 1A, 1B) under temperature-controlled atmosphere under positive pressure (relative to local ambient pressure) to bring DUTs close to testing temperature. The temperature inside the thermal chamber 102 is controlled in part by introducing temperature-controlled gas, e.g., temperature controlled clean dry air/compressed dry air. Further, the input station 107, the output station 118 and the TPS 106 may be in a dry chamber 122 (FIG. 1A) under positive pressure (relative to local ambient pressure) to reduce condensation on the DUTs upon introduction into the thermal chamber 102.

As illustrated in FIG. 1C, electronic device testing system 100 may be connected to one or more heat exchange systems 126 through inlet and outlet pipes. In some embodiments, the heat exchange system 126 may comprise one or more condensing units for circulating temperature-controlled fluid including liquid nitrogen or other fluid to cool the thermal chamber 102. In some embodiments, the electronic device testing system 100 may use chilled clean dry air/compressed dry air (“CDA”) in the thermal chamber 102 to maintain the temperature-controlled atmosphere therein. In some embodiments, a temperature-controlled gas may be introduced into the thermal chamber 102 through a temperature-controlled gas conduit 136 (FIGS. 1B, 1C) disposed closer to the soak up station 112 and the soak down station 114, along with fans or blowers. Additional heat exchange system 126 may be employed to provide a cold source for a contactor included in the testing station 116, which may be configured, in conjunction with a heater, to provide temperature control of the DUT leads during testing. Additional heat exchange systems 126 may also be employed to provide a cold source for a plunger/thermal head included in the testing station 116, which may be configured, in conjunction with a heater, to provide temperature control of the DUT during testing. The temperature of the DUT may be maintained, e.g. at a temperature between about −55° C. and 200° C.

Among other technical features described throughout the application, in various embodiments, in operation of the system 100 according to embodiments, the DUTs are transferred within the system 100 through usage of the carriers 108, without handling DUTs out of the carriers 108 as the DUTs are transferred through different stations. Unlike existing systems, once the DUTs are transferred onto the carriers 108, the station-to-station transfers and testing of the DUTs are performed without removing them from the carriers 108, which greatly reduces device displacement events, as there may not be a need for handling the DUTs using, e.g., vacuum handlers. until after the testing is completed. The reduced handling of the DUTs greatly reduces the probability of displacing the DUTs, which has traditionally been one of the biggest throughput limiters of IC testing.

The tray stacks 104 can include trays of DUTs that are to be tested or have completed testing. Each tray in the tray stack 104 can include one or more DUTs. For example, each tray in the tray stack 104 can include one, two, four, eight, twenty, fifty, or other number of DUTs. In the illustrated implementation, the tray stacks 104 are positioned outside of the testing chamber 102.

In some implementations, in addition to the control of the ambient temperature in the thermal chamber 102, there can also be a pressure difference between the thermal chamber 102 and the area in which the tray stacks 104 are positioned. For example, the thermal chamber 102 may have, e.g., a positive pressure of temperature-controlled dry gas such as clean dry air/compressed dry air. The positive pressure may be maintained by a continuous purge of the thermal chamber 102 with the temperature-controlled dry gas. Similarly, the dry chamber 122 may also have a positive pressure e.g., a positive pressure of temperature-controlled dry gas. The positive pressure configurations can keep moisture from condensing on the DUTs or other parts of the system, which can interfere with the testing. For example, without such purge, DUTs that are cooled may collect excessive moisture condensation.

The TPS 106 can carry, or otherwise transfer, trays from the tray stacks 104 into the testing chamber 102. In some embodiment, the TPS 106 includes tray frames that temporarily physically couple to a tray of the tray stack 104 and carry the tray into the testing chamber 102. The TPS 106 can carry, or otherwise transfer trays, such as trays of DUTs having completed testing, from the dry chamber 122 to the tray stacks 104. The TPS 106 can include, or be connected to, the input station 107 and the output station 118.

The PnP head 128 can transfer DUTs from a tray inputted into the dry chamber 122 from the TPS 106 and place them onto carriers 108 on the input station 107. The PnP head 128 can also carry DUTs from a carrier 108 on the output station 118 and place them onto trays in the TPS 106 to be carried out of the dry chamber 122. In various implementations, the input station 107 and the output station 118 can be configured to pick up DUTs one at a time, or in sets. For example, the PnP head 128 can include one or more vacuum contact points to temporarily couple the DUTs to transfer them to the carrier 108 on the input station 107 or from the carrier 108 on the output station 118.

A carrier assembly includes a carrier 108 (also referred to as a “body” of the carrier assembly) and one or more coupons 180. In some implementations, a carrier assembly can correspond to a carrier 108 of FIGS. 1A-1C. The carrier 108 has formed thereon a plurality of coupon receptacles (also referred to as a “coupon pocket”) into which the coupons can be removably inserted. The coupon receptacles can be arranged in an array, e.g., an array of rows and columns. The carrier 108 can include one or more alignment holes and one or more alignment pins. It will be appreciated that for illustrative purposes only, an illustrated carrier assembly may include eight total coupons 180, arranged in two rows of four coupons 180. However, other numbers of coupons 180 and other arrangements of coupons 180 may be used. For example, eight coupons 180 may be arranged in a single row of eight coupons 180. As another example, carrier assembly may have a single coupon 180 or may have more than eight coupons 180 (e.g., 32 coupons 180). In some implementations, the coupons 180 are not arranged in rows.

Each coupon may be configured to carry one or more DUTs. While placed in a carrier, a coupon may have up to six degrees of freedom of movement, including three linear degrees of freedom along lateral, e.g., x and y directions, and the vertical direction, e.g., z direction, and three rotational degrees of freedom about the x, y and z axes. The degrees of freedom may be provided by, e.g., springs holding the coupons within the carrier. The degrees of freedom may allow the coupons move within the coupon without damaging the coupons and/or dislodging the coupon. The coupon may allow a testing orientation to remain. For example, the pin orientation of the DUT may be maintained as the DUT moves within the coupon.

The carriers 108 may be transported between different stations by the carrier retainer disks 109. The carrier retainer disks 109 are configured to hold and transfer the carriers 108 from one station to the next. When being transferred, the carriers 108 are coupled or temporarily coupled to the carrier retainer disks 109. In some implementations, the carries 108 are placed on the carrier retainer disks 109. In the illustrated implementation, the carrier retainer disks 109 rotate the carriers 108 sequentially from the input station 107 to the soak up station 112, followed by the soak down station 114, followed by the testing station 116, and followed by the output station 118.

As FIG. 1D shows, the carrier retainer disks 109 are configured such that, as they are rotating, the orientations of the carriers 108 are kept substantially constant. FIG. 1D shows an example platter assembly 140 configured for such operation. The platter assembly 140 includes a torque motor 144 configured to rotate a platter having a plurality of arms, each having disposed thereon a carrier retainer disk 109 configured to carry a carrier 108. The platter assembly 140 additionally includes a sun gear 152 and a plurality of planet gears 156, each corresponding to a carrier retainer disk 109. The torque motor 144 causes the sun gear 152 to rotate, which in turn causes the planet gears 156 to rotate. The planet gears 156 and the carrier retainer disks 109 are toothed to mesh with each other such that the carrier retainer disks 109 rotate in the opposite sense as the sun gear 152. For example, as the carrier retainer disks 109 are rotating from one station to the next in a clockwise direction about a central axis 125 of the system they are rotated in a counterclockwise direction to offset for the rotations of the carrier retainer disks 109 about their own local central axes 145.

The thermal staging area 110 can heat the DUTs and/or cool the DUTs to set temperatures, such as a testing temperature. A testing temperature can refer to a temperature the DUTs are to be at when testing begins. The thermal staging area 110 can include a soak up station 112 and a soak down station 114. In some instances, the time required for a DUT to reach a testing temperature in the thermal staging area 110 may be different (e.g., shorter or longer) than the time required for testing in the testing station 116. The thermal staging area 110 can include multiple soak stations for the carriers 108. The carriers 108 can be brought into a first soak station 112 in the thermal staging area 110 where the carriers 108 are soaked for an amount of time (e.g., approximately the time it takes to complete a test of DUTs in the testing station). Then the carriers 108 can be brought into a second soak station 114 of the thermal staging area 110 where the carriers are further soaked for an amount of time (which can be approximately equal to the amount of time in the first station of the thermal staging area 110).

In embodiments where soak stations are configured to stack and unstack multiple carrier, the carriers 108 can be brought into the first soak station 112 (which may also be referred to as a soak up station) and/or the second soak station 114 (which may also be referred to as a soak down station) by the carrier retainer disks 109 where each new carrier 108 is added to a stack. A carrier 108 can be removed from a stack in the soak up station 112 and/or the soak down station 114 and placed back onto the carrier retainer disks 109. A carrier 108 can remain in a stack in the soak up station 112 and/or soak down station 114. In some implementations, carriers 108 can be rotated by the carrier retainer disks 109 into the soak up station 112 where they can be stacked. Each carrier 108 arriving at the soak up station is inserted into a slot created at the bottom of the stack of carriers 108 such that vertical handling of the carriers is reduced. The DUTs in their respective carrier soak to a temperature setpoint as the carriers 108 are stacked up. The stack of carriers 108 can be rotated by a carrier retainer disk 109 from the soak up station 112 into the soak down station 114, from which the carriers 108 are singulated and moved to the testing station 116.

While FIGS. 1A-1C illustrate the thermal staging area 110 as having two separate soak stations, in various implementations, the thermal staging area 110 may have a single station or more than two stations. In some implementations, the thermal staging area 110 may be omitted altogether and the carriers transferred directly from the input station 107 to the testing station 116. In yet other implementations, the testing station may be between two soak stations.

Following the thermal staging area 110, the carriers 108 can be removed from the stack one by one and rotated into the testing station 116 (also referred to as a “testing chamber”) by the carrier retainer disks 109. The electrical testing of the DUTs is performed in the testing station 116. The testing station 116 can include contactors that can create an electrical connection while physical contact is made between the contactors and input/output (“I/O”) points of the DUTs (e.g., I/O contact pins, I/O contact pads, and/or the like on the DUTs). The testing station 116 may apply a testing signal to the DUTs. For example, the testing station 116 can apply electrical power or current to the DUTs via the contactors. The testing station 116 can measure one or more parameters of the DUTs during testing. For example, the testing station 116 can measure changes in temperature of the DUTs, output power of the DUTs, and/or other parameters in response to the applied testing signal. The testing station 116 may lock the DUTs into a position in the coupons, removing the six degrees of movement the DUTs have within the coupon during testing. In some implementations, the testing station 116 can include an active thermal control (“ATC”) system that uses a heating block to control the temperature at the thermal head or the plunger, and can raise and/or lower the temperature of the DUTs during testing. Aspects of the testing station 116 will be described in more detail below with respect to FIGS. 1E-1I.

### Example Device Testing Components—Testing Station

FIGS. 1E and 1F illustrate example aspects of testing DUTs. FIG. 1E illustrates portions of a testing station (e.g., testing station 116) according to various embodiments. The testing station 116 can include a socket layout kit (SLK) 160 with one or more plunger assemblies 162 positioned vertically above (or below) a carrier 108 with one or more DUTs positioned therein. The testing station 116 can include a contactor assembly 192 with a loadboard positioned vertically below (or above) the carrier 108.

According to various embodiments, prior to testing, the carrier 108 with DUTs previously loaded is positioned within the testing station 116 (e.g., by a carrier retainer disks 109). Once the carrier 108 is positioned within the testing station 116, the SLK 160 is lowered such that the one or more plunger assemblies 162 apply a force on the coupons positioned on the carrier 108, disposing the carriers into a testing position in which the DUTs make electrical and physical contact with contactors 198 of the contactor assembly 192. As the plunger assemblies 162 apply the force to the coupons (e.g., as elastic members of the coupons elongate), but before the coupons are in the testing position, each coupon can have up to three independent linear degrees of freedom of movement within the coupon receptacle and up to three independent angular degrees of freedom of movement within the coupon receptacle. These degrees of freedom can allow the coupons and DUTs positioned therein to align with the contactors with an increased margin of error in the positioning of the plunger assemblies 162, the carrier 108, the coupons, the DUTs, and/or the contactors. In particular, higher error tolerance can allow for the DUTs to align into the testing position with improved contact between the DUTs and the plunger and/or the contactor. This increased margin of error can increase the success rate of test performance, decrease the need to retest DUTs, decrease the potential of damage to the DUTs or contactors, improve thermal control and/or provide other benefits described herein or apparent from this disclosure.

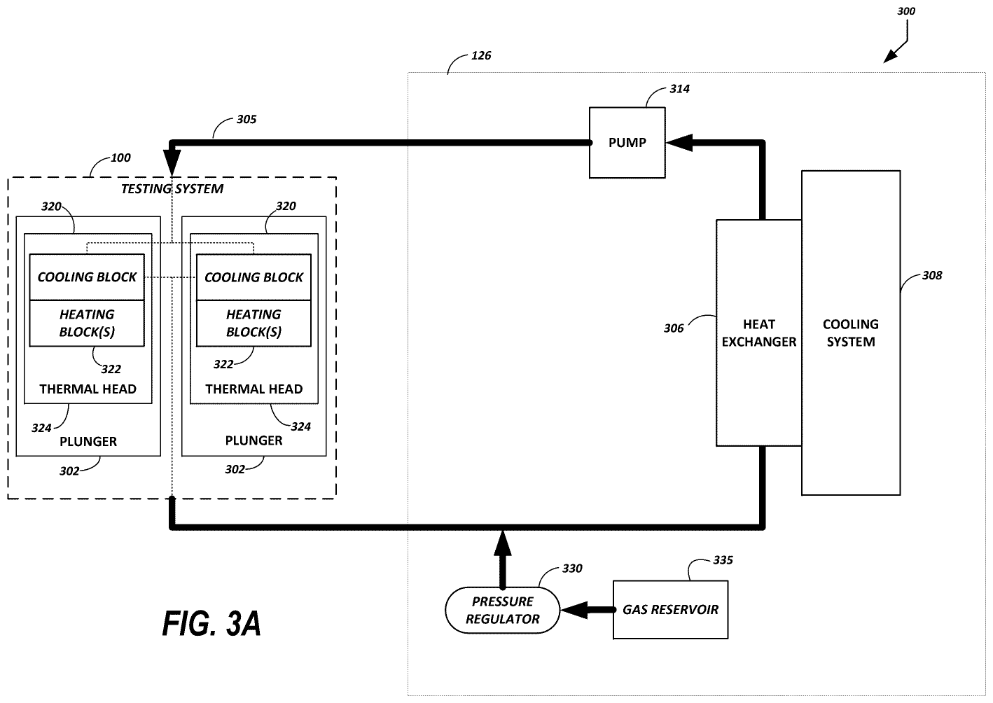

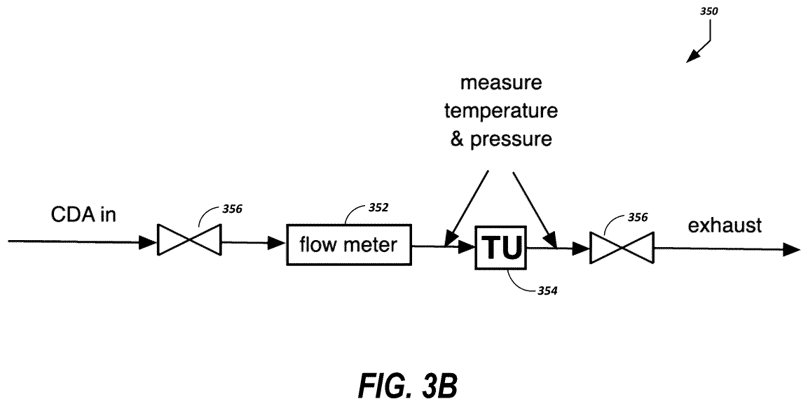

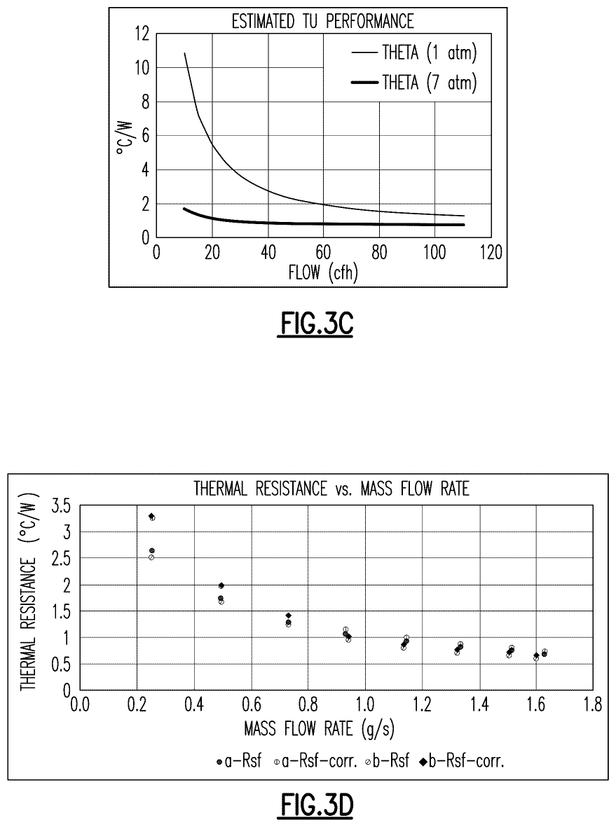

FIG. 1F illustrates a cross section of parts of a testing station according to various embodiments. In the illustrate embodiment, the coupon 180 is in a testing position with the DUT 170 in physical and electrical contact with the contactors 198. A plunger assembly 162 with a thermal head 163 and a pedestal 165 is illustrated as engaging the coupon 180 and/or the DUT 170. The thermal head 163 and/or a pedestal 165 can collectively be referred to as a “plunger” 302 (e.g., the plungers in FIGS. 1G-1I and 3). The thermal head 163, the pedestal 165, alignment features 167 (described below with respect to FIG. 1I), and supporting structures can collectively be referred to as a “nest plunger” 164 (e.g., the nest plunger 164 illustrated in FIGS. 1H and 1I). Aspects of the one or more plunger assemblies 162 will be described in more detail below with respect to FIGS. 1G-1I.

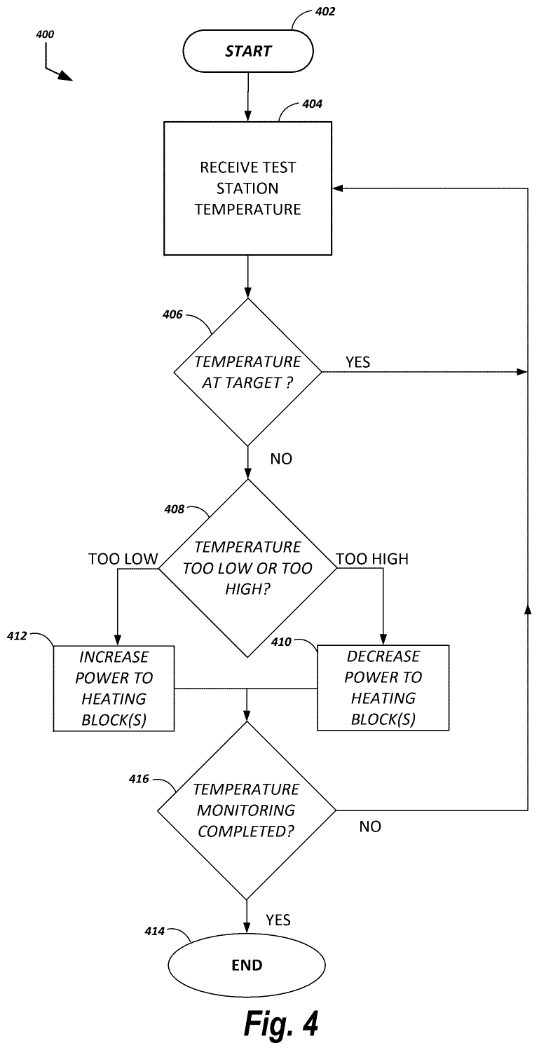

During testing, the plunger assembly 162 can physically secure the coupon 180 in the testing position and/or the DUT 170 against the contactors 198. The thermal head 324 can provide thermal control (e.g., ATC or passive thermal control). For example, the thermal head 324 implements an ATC system that can raise and/or lower the temperature of the DUT 170 during testing. As another example, the thermal head 324 may be a heat sink without active heat dissipation. In these embodiments, the 324 may have a thermal mass sufficient to conduct and dissipate the thermal energy from the DUT 170 during testing to maintain a testing temperature. The pedestal 165 may facilitate thermal conductions between the thermal head 324 and the DUT 170. For example, the pedestal 165 may comprise suitable thermally conductive materials to efficiently transfer thermal energy to and from the DUT 170 and the thermal head 324. The pedestal 165 may additionally provide a physical interface and provide a securing force on the DUT 170, such that the DUT 170 remains in a fixed position during electrical testing. In some embodiments, the pedestal 165 is omitted and the thermal head 324 contacts the DUT 170 directly. Aspects of the plunger 302 and the thermal head 324 and ATC will be described in more detail below with respect to FIGS. 3-4.

The contactors 198 can be implemented on or integrated with a socket 196 and positioned on a loadboard. The loadboard may be part of or attached to the contactor assembly 192 and raised up to coupons and DUTs (or remain stationary and have the coupons and DUTs lowered to) when the coupons are in the testing position.

FIGS. 1G and 1H illustrate example SLKs 160 according to various embodiments. FIG. 1G illustrates the SLK 160 with the thermal heads 324 of the plungers included in the plunger assemblies 162 exposed. FIG. 1H illustrates the SLK 160 with the nest plungers 164 included in the plunger assemblies 162.

FIG. 1I illustrates the nest plunger 164 according to various embodiments. The nest plunger 164 may be used to apply a force on a coupon 180 and/or a DUT 170. The nest plunger 164 may displace a coupon 180 relative to a carrier 108 of a carrier assembly during testing of one or more DUTs. In the illustrated embodiment, the nest plunger 164 includes a plunger 302, alignment features 167, and fasteners 169.

The plunger 302 may be configured to be inserted into a DUT pocket of a coupon 180. The plunger 302 may contact the DUT 170 and apply a force on the DUT and coupon, such that the DUT or coupon has restricted movement in at least a vertical axis, e.g., a z direction. As such, in some embodiments, a combination of the nest plunger 164 and the socket 196 may be used to restrict the movement (e.g., remove the six degrees of freedom of movement) of a DUT 170 and/or coupon 180. Further, the plunger 302 may include the thermal head 324 and/or the pedestal 165. The pedestal 165 may facilitate thermal conductions between the thermal head 324 and the DUT 170. For example, the pedestal 165 may comprise suitable thermally conductive materials to efficiently transfer thermal energy to and from the DUT 170 and the thermal head 324. The pedestal 165 may additionally provide a physical interface and provide a securing force on the DUT 170, such that the DUT 170 remains in a fixed position during electrical testing. In some embodiments, the pedestal 165 is omitted and the thermal head 324 contacts the DUT 170 directly. The plunger 302 can include an active thermal control (“ATC”) system that uses a heating block/heater to control the temperature at the thermal head or the plunger and thus can raise and/or lower the temperature of the DUTs during testing. The plungers of other illustrated embodiments may include the same or similar aspects of the plunger 302 illustrated here. Aspects of the plunger and thermal head and ATC will be described in more detail below with respect to FIGS. 3-4.

The alignment features 167 may be configured to be inserted into some, or all, of the plurality of holes of a coupon 180. The alignment features 167 may help ensure alignment between the DUT pocket and the plunger 302. In the illustrated embodiment, the alignment features 167 are configured to be inserted into the holes at diagonal positions. The alignment features 167 may prevent the coupon 180 from moving laterally, e.g., in x and y directions, with respect to the nest plunger 164 (while allowing the lateral movement with respect to the contactor). The fasteners 169 may couple the nest plunger 164 to the one or more plunger assemblies 162. The fasteners 169 can include screws, rivets, pins, and/or other fasteners.

### Process for Testing a DUT

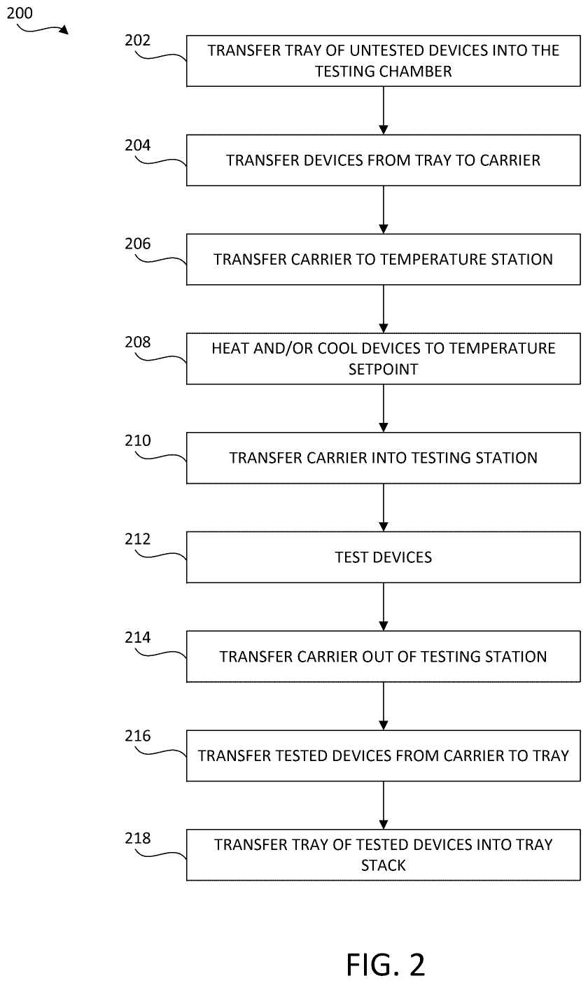

FIG. 2 is an example process 200 of testing DUTs using an electronic device testing system 100, according to various embodiments. Process 200 may contain more, or fewer, steps than illustrated in FIG. 2. Some of the steps of process 200 may be repeated. Further, the steps of process 200 may be performed in other orders than illustrated in FIG. 2.

At block 202, the electronic device testing system 100 transfers a tray of untested devices or DUTs into the testing chamber 102. For example, the TPS 106 may use a tray frame to carry a tray of untested devices from the tray stacks 104 into the testing chamber 102. At block 204, the electronic device testing system 100 transfers devices from the tray into one or more carriers 108. For example, the input station 107 may carry individual ones of the devices from the tray and place them into coupons on the carriers 108. In some implementations, the tray may have a larger number of devices than can be held in a carrier 108. In these implementations, the devices in the tray may be loaded into multiple carriers 108. In other implementations, the tray may have a smaller number of devices than can be held in a carrier 108. In these other implementations, the electronic device testing system 100 may load multiple trays of untested devices into a single carrier 108.

At block 206, the electronic device testing system 100 transfers a carrier 108 into the thermal staging area 110. For example, a carrier retainer disk 109 can rotate the carrier 108 into the thermal staging area 110. The carrier 108 may be placed in one or more stacks of carriers 108 within the thermal staging area 110.

At block 208, the devices in the carrier 108 are heated and/or cooled to a temperature setpoint within the thermal staging area 110. For example, the thermal staging area 110 may use convection, radiation, and/or other heating processes [conduction?] to heat the devices. As another example, the thermal staging area 110 may use cold gases, heat sinks, and/or other cooling processes to cool the devices. At block 210, the carrier 108 is transferred into the testing station 116. For example, the carrier retainer disk 109 can rotate the carrier 108 into the testing station 116.

In some implementations, the carrier 108 may be in the thermal staging area 110 for multiple testing cycles. The thermal staging area 110 can include multiple stations for setting and soaking the temperature of the devices at different temperatures. In some of these implementations, the electronic device testing system 100 may stack carriers 108 in the soak up station 112. For example, as the carrier 108 is transferred to the thermal staging area 110 at block 206, the carrier 108 can be removed from the carrier retainer disk 109 and added to the stack. The electronic device testing system 100 may remove the carriers 108 from a stack in the soak down station 114 one by one. For example, as a carrier 108 is transferred to the testing station 116 at block 210, the carrier 108 can be removed from a stack in the soak down station 114 and placed on a carrier retainer disk 109 and rotated by the carrier retainer disk 109 into the testing station 116. In some implementations, a stack of carriers can be transferred from the soak up station 112 to the soak down station 114. In other implementations, the devices may not be subjected to heat or cold treatments. In these implementations, the electronic device testing system 100 may cause a carrier 108 to bypass the thermal staging area 110. For example, the carrier 108 may not be added to a stack and continued to be carried through the thermal staging area 110. In some implementations, carriers 108 are singulated from the stack and transferred to the testing station 116.

At block 212, the electronic device testing system 100 tests the devices. The electronic device testing system 100 may move the carrier and/or contactors of the testing station 116 such that the contactors make physical contact with I/O points of the devices. The testing station 116 may move a thermally controllable thermal head/plunger onto the DUTs to lock the devices into a position in the coupons. The testing station 116 may apply a test signal, e.g., a load, to the devices and measure one or more parameters on the devices in response to the test signal. The electronic device testing system 100 may record the results of the test for each device, such as the parameter values, and associate the results with the device.

At block 214, the electronic device testing system 100 transfers the tested devices out of the testing station 116. For example, the electronic device testing system 100 can move the carrier back onto a carrier retainer disk 109 and rotate the carrier retainer disk out of the testing station 116. At block 216, the electronic device testing system 100 transfers the tested devices from the carrier 108 to one or more trays. For example, the output station 118 may carry the tested devices from the coupons of the carrier 108 to the tray. At block 218, the electronic device testing system 100 transfers the tray of tested devices into the tray stacks 104. For example, the TPS 106 may carry a tray of tested devices from the testing chamber 102 to the tray stacks 104. In various implementations, the electronic device testing system 100 may index and track the devices throughout process 200. For example, the electronic device testing system 100 may index the devices as they are transferred into the testing chamber 102 and associate the results of the test with the indexed devices, such that as the devices are transferred into the trays and out of the testing chamber 102, each individual device and test result are known for each position of the device in the tray.

According to various embodiments of the method/process 200, once the DUTs are individually transferred to a carrier using the PnP head, the DUTs are transferred within the system 100 (FIGS. 1A-1C) through usage of the carriers 108, without handling DUTs out of the carriers 108 as the DUTs are transferred through different stations. For example, blocks 206-214 above may be performed without removing the DUTs from the carriers 108. Unlike existing methods, once the DUTs are transferred 202 onto the carriers 108, the station-to-station transfers and testing of the DUTs are performed without removing them from the carriers 108, which greatly reduces device displacement events, as there may not be a need for handling the DUTs using, e.g., vacuum handlers. Until after the testing is completed. The reduced handling of the DUTs greatly reduces the probability of displacing the DUTs, which has traditionally been one of the biggest throughput limiters of IC testing.

### Temperature Control System-Integrated Circuit Device Testers

FIG. 3A is an embodiment of an environment 300 of a closed circulation loop 305 which uses a pressurized gas phase heat transfer medium, such as clean dry air/compressed dry air, to thermally communicate with a device under test (“DUT”). The environment 300 can be configured to maintain a target temperature of one of more DUTs and a target gas pressure within the closed circulation loop 305. The environment 300 can include the testing system 100 connected to the heat exchange system 126. As shown, the heat exchange system 126 includes a closed circulation loop 305, which connects the testing system 100 to a heat exchanger 306.

The testing system 100 includes one or more plungers 302. The plunger 302 is configured to be in thermal communication with a first portion of the closed circulation loop and in further thermal communication with the DUTs. The plunger can be a mechanical device located at a testing station within the testing system 100. The plunger is configured to be in physical contact with the DUT.

As described above, e.g., with respect to FIG. 1F, the plunger 302 includes a thermal head 324. In some embodiments, the thermal head 324 physically contacts the DUT. The thermal head 324 may further include one or more thermal contact units configured to conduct and dissipate the thermal energy from the DUT during testing to maintain a testing temperature. The thermal contact units located within the plunger can be a suitable device adapted to absorbing heat into the closed circulation loop 305. In other embodiments, the plunger may further include a pedestal to facilitate thermal conduction between the thermal head 324 and the DUT, wherein the pedestal physically contacts the DUT. The pedestal may comprise suitable thermally conductive materials to efficiently transfer thermal energy to and from the DUT and the thermal head. The pedestal may additionally provide a physical interface and provide a securing force on the DUT, such that the DUT remains in a fixed position during testing.

The thermal head 324 includes one or more cooling blocks 320. In some embodiments, the cooling blocks 320 may include a heat sink with passive heat dissipation. In some embodiments, the cooling block 320 can be a mechanical device, which may be a mechanical system for routing heat transfer medium throughout the cooling block. In an alternative embodiment, a cooling block 320 can include an automatic flow control (“AFC”) valve, a mechanical device which can modulate a flow of fluid through a cooling block 320. The AFC value can modulate flow of gas to correspond with temperature needs, allowing more gas to flow when more cooling is needed and reducing an amount of gas flowing when less cooling is needed. The cooling block 320 may also include thermally conductive metals or other material to transfer heat to the gas phase heat transfer medium. In some embodiments, the cooling block 320 includes a network of cooling conduits forming a part of the closed circulation loop.

In some embodiments, the thermal head 324 may further include one or more heating blocks 322. The heating blocks are configured to be closer to the DUT than the cooling blocks. In some embodiment, the heating blocks are configured to be closer to, more particularly, the network of cooling conduits. The heating blocks 322 can be mechanical and electrical systems containing circuits which receive electrical energy and generate thermal energy. In some embodiments, the heating blocks 322 may further include thermally conductive metals or other thermally conductive material to transfer heat to or from the one or more thermal heads/plungers.

In some embodiments, a thermal head 324 can further include thermally conductive ceramic, metals, or other material coupled to the cooling blocks 320 and the heating blocks 322 to transfer heat to or from one or more DUTs which the thermal head 324 physically contacts with during testing.

In some embodiments, the method of distributing heat to and from a DUT may include circulating the gas phase heat transfer medium through a corresponding cooling block 320. The gas phase heat transfer medium can be passed through a cooling block 320 at a constant pressure and flow rate. Also, to set the temperature of the thermal head to a designated temperature, cooling power delivered to the cooling block 320 in the thermal head can be modulated. In this way, when a testing setup uses a colder thermal head during the performance of the tests, more cooling power can be delivered to the cooling block 320, and when a higher temperature for the thermal head is desired, less cooling power can be delivered to the cooling block 320. In some embodiments, the AFC value can modulate flow of gas to correspond with the cooling power, allowing more gas to flow when more cooling power is needed and reducing the amount of gas flowing when less cooling power is needed. In this manner, the system may be configured for testing under differing thermal environments by setting different base settings for the cooling power to be delivered during different performance tests.

Besides setting the thermal head to a particular temperature by circulating the gas phase heat transfer medium through the cooling block 320, the system may also be configured to allow relatively rapid modulation of the temperature of the thermal head by incorporating the heating blocks. In some embodiments, the heating blocks are electrically controllable. In this manner, the thermal head may have its temperature modulated according to thermal demands of the DUT. Thus, the cooling power of the corresponding cooling blocks is allowed to be fully realized at the thermal head. For the DUT that needs less cooling power, the heating blocks may be activated to raise their temperature to allow the corresponding thermal head to maintain a target temperature of the DUT. It will be appreciated that in this circumstance the thermal head may still be relatively cold even if the heating blocks are activated, but not as cold as if the heating blocks were inactivated.

The closed circulation loop 305 circulates the gas phase heat transfer medium through the cooling blocks 320 and the heat exchanger 306. In some embodiments, the gas phase heat transfer medium may be clean dry air/compressed dry air (“CDA”). In other embodiments, the gas phase heat transfer medium may be a composition substantially different from the ambient air. The gas phase heat transfer medium may be an inert gas, such as helium, argon, or neon. Advantageously, in further embodiments, the gas phase heat transfer medium does not include a hydrocarbon or a hydrofluorocarbon (HFC). The gas phase heat transfer medium may also be nitrogen or hydrofluoroether (HFE). In these embodiments of the present disclosure, the gas phase heat transfer medium is not in a liquefied form within the closed circulation loop 305.

The closed circulation loop 305 has pressurized gas phase heat transfer medium at a pressure greater than an atmospheric pressure (1 atm or 1 bar). A target gas pressure and flow rate can be dependent upon the heat transfer medium, given that different heat transfer mediums have different abilities to conduct heat and opposition to the heat. In some embodiments, the pressure of the gas phase heat transfer medium within the closed circulation loop 305 can be between 2 bar and 30 bar. In a preferred embodiment, the gas phase heat transfer medium within the closed circulation loop 305 may be at the pressure of about 7 bar to 10 bar. In another preferred embodiment, the compressed dry air within the closed circulation loop 305 may be at the pressure of about 4.5 bar to 8 bar. A range of thermal resistance of a thermal unit between 3.5° C./W to 0.5° C./W can be achieved by a range of mass flow rate between 0.2 g/s to 1.8 g/s. The simulation and experimental results related to the pressure, flow rate, and thermal resistance using the pressurized gas phase heat transfer medium will be illustrated below in conjunction with FIGS. 3B-3D.

In the embodiments of the present disclosure, the gas phase heat transfer medium may be at a temperature lower than the DUT such that a net flow of heat occurs from the DUT to the gas phase heat transfer medium. With different DUTs requiring different testing temperatures, the target temperature can be dependent upon which DUT is being tested. The temperature of the gas phase heat transfer medium can be controlled between −80° C. and 200° C. The temperature of the DUT may be maintained, e.g. at a temperature between about −55° C. and 200° C., e.g., at about −55° C., −40° C., −20° C., 0° C., 20° C., 40° C., 60° C., 80° C., 100° C., 120° C., 140° C., 160° C., 180° C., 200° C. or a temperature in a range defined by any of these values.

In some embodiments, the closed circulation loop 305 may also include a pressure regulator 330 which connects the closed circulation loop 305 to a pressurized gas reservoir 335 which can be used to recharge and control the pressure of the gas phase heat transfer medium within the closed circulation loop 305. The gas reservoir 335 can include a pressurized container filled with one of a plurality of gases or a mixture of two or more gases. The gases can be air (a combination of gases with a composition approximately matching that of Earth's atmosphere), nitrogen, argon, helium, neon, or any other suitable gas. Gases within the gas reservoir 335 can be kept at a higher pressure than that within the closed circulation loop 305 so as to enable gas within the gas reservoir 335 to enter the closed circulation loop 305 via the pressure regulator 330 when it experiences a pressure gradient between the gas reservoir 335 and the closed circulation loop 305 of at least a threshold level.

The pressure regulator 330 may be a unidirectional pressure regulator connecting the pressurized gas reservoir 335 to the closed circulation loop 305. The pressure regulator 330 can include a mechanical device which can be used to control a gas flow, wherein controlling the flow can be done by expanding (“opening”) or reducing (“closing”) an opening between the closed circulation loop 305 and the pressurized gas reservoir 335, wherein expanding the opening can increase the flow and reducing the opening can reduce the flow. Whether an opening is expanded or minimized can depend upon the absolute pressure of the pressurized gas reservoir 335 as compared to the pressure within the closed circulation loop 305. If the absolute pressure of the gas in the pressurized gas reservoir 335 is greater than the recirculating gas within the closed circulation loop 305, the opening can be opened or expanded. And if the absolute pressure of the gas in the pressurized gas reservoir 335 is not greater than the recirculating gas within the closed circulation loop 305, the opening may be closed or minimized. To enable the gas to move in a desired direction, there must be a positive pressure gradient between the pressurized gas reservoir 335 and the closed circulation loop 305. As gases within the gas reservoir 335 are kept at a higher pressure than the gas within the closed circulation loop 305, gas within the gas reservoir 335 enters the closed circulation loop 305 via the unidirectional pressure regulator 330 when the regulator experiences a pressure gradient between the gas reservoir 335 and the closed circulation loop 305 of at least a threshold level.

The closed circulation loop 305 may also include a pump 314, which is configured to circulate the gas phase heat transfer medium around the closed circulation loop 305.

The heat exchanger 306 is in thermal communication with a second portion of the closed circulation loop 305. The heat exchanger 306 is in further thermal communication with a cooling system 308 which provides cooling power to the heat exchanger and transfers heat away from the closed circulation loop 305. More particularly, the heat exchanger transfers heat away from a second portion of the closed circulation loop 305. The gas phase heat transfer medium going through the heat exchanger 306 may reach a target temperature thereof. Without limitation, the heat exchanger 306 may include a plate fin heat exchanger which includes one or more plates, e.g., plates having length and width that are substantially greater than a thickness to enhance heat transfer, that are configured to efficiently transfer heat from the closed circulation loop 305 to the cooling system 308. The one or more plates may be made of any thermally conductive material, such as brass, copper, stainless steel, aluminum, or any other material.

The cooling system 308 may use a suitable system or device for providing cooling power, such as a cooling system using chilled water or liquid nitrogen, a refrigeration system which includes one or more condensing unit, or another system which can provide the proper cooling power to the heat exchanger 306.

FIG. 3B is a schematic diagram demonstrating an experimental setup 350 to measure the thermal resistance of a TU using a gas phase heat transfer medium. The setup 350 includes a 14 mm matrix thermal unit (“TU”) 354 for thermal communication with an heat source and a flow meter 352 for measuring the actual flow of the gas phase heat transfer medium. The setup 350 also includes an inlet pipe for introducing the gas phase heat transfer medium and an outlet pipe for exhausting the gas phase heat transfer medium. The setup 350 also includes valves 356 for adjusting the pressure of the gas phase heat transfer medium. The gas phase heat transfer medium is forced through the experimental setup 350 from the left to right as illustrated in the diagram. The actual flow rate is measured at the flow meter 352 before going into the TU 354. A mass flow rate can be calculated from that measurement and an inlet pressure. The temperature and pressure are measured both before and after TU. In some settings, the TU does not have a resistance temperature detector (RTD) to measure the heat sink temperature, and a thermocouple may be used. In another setting, a TU with an RTD may be used.

FIG. 3C shows the simulation about the thermal properties of the TU using the compressed dry air as the gas phase heat transfer medium. The x-axis is the flow rate, and its unit is cubic feet per hour (cfh). The y-axis is the estimated thermal resistance calculated based on the simulation, and its unit is ° C./W. The simulation demonstrates that using the atmospheric air without compression can only achieve acceptable thermal resistance at relatively fast flow rates. However, using compressed air significantly reduces the thermal resistance, and the dry air compressed at 7 atm can achieve lower thermal resistance with relatively low flow rates. Using the experimental setup as illustrated in FIG. 3B to verify the simulation results, FIG. 3D shows the experimental results of the thermal resistance of the TU using the compressed dry air as the gas phase heat transfer medium. The x-axis is the calculated mass flow rate, and its unit is gram per second (g/s). The y-axis is the thermal resistance based on measurements, and its unit is ° C./W. The experimental results indicate that, at an absolute inlet pressure between 5 and 7 atm (preferably 4.5 to 7 atm), the experimental results are close to the simulation results. A below 1.0° C./W thermal resistance Rsf can be obtained with mass flow rates greater than 1 mg/s. The experiments are conducted under different temperatures of the heat source (“a” represents a heater at 100° C. and “b” represents the heater at 150° C.) and the results show similar thermal resistance values.

### Temperature Control Method—Integrated Circuit Device Tester

FIG. 4 is a flow chart depicting a method 400 for maintaining a target temperature of a DUT employing an active thermal control process. Without limitation, the method 400 as illustrated in FIG. 4 implements an active thermal control process with mainly adjusting the heating block 322. The cooling block 320 may also be activated to provide cooling power simultaneously at each step of the method 400. At 402, the method 400 begins, and at 404, a temperature from a DUT can be received (also referred to as a “device temperature”), wherein the device temperature can be measured by a temperature sensor located within the DUT or derived from a thermally dependent electrical signal originating from a DUT. In addition, the temperature may also be measured at one or more positions, or by other mechanisms, within the testing system 100. For example, the temperature of the DUT may be measured by using the output of a pin on the DUT during the test. Many current integrated circuits include output pins or solder balls which output electrical signals related to the temperature of the DUT. This allows the temperature of the DUT to be measured during normal operations after it is installed into a system. In some embodiments, the temperature of the DUT is estimated by one or more sensors or signals within the system which are configured to output an estimated DUT temperature.

At 406, the system can determine if the device temperature matches a predefined temperature target. If the device temperature matches the temperature target, the system can return to step 404, receiving another device temperature from the temperature sensor or other temperature measurement method. If the device temperature does not match the target temperature, the method 400 moves to step 408 to determine whether the device temperature is too low or too high.

If the device temperature is too low, the method 400 moves to state 412 to increase electrical power delivered to a heating block 322 corresponding to the DUT's location with respect to the thermal head 324, to increase the temperature of the thermal head and plunger contacting the DUT.

If the device temperature within the DUT is determined to be too high at the decision step 408, the method 400 moves to a step 410 to decrease electrical power delivered to a heating block 322 corresponding to the DUT's location with respect to the thermal head 324, to decrease the temperature of either the thermal head and plunger contacting the DUT.

After either increasing or decreasing the temperature of the DUT, the method 400 can move to a step 416 to determine if monitoring a device temperature within a DUT is complete. If not, the method 400 can return to step 404 and receive additional device temperatures. If monitoring is complete, the method can end at an end step 414, wherein ending the method 400 can include ceasing the monitoring of device temperature and/or making modifications to device temperature. In most embodiments, the system will continuously monitor the temperature of the thermal head or DUTs as devices are being processed. However, in some embodiments, when the system is done processing DUTs, temperature monitoring can be completed if a button is pressed or an electronic signal is received which corresponds to tests within an electrical device testing system 100 being complete.

### Temperature Control System-Data Center

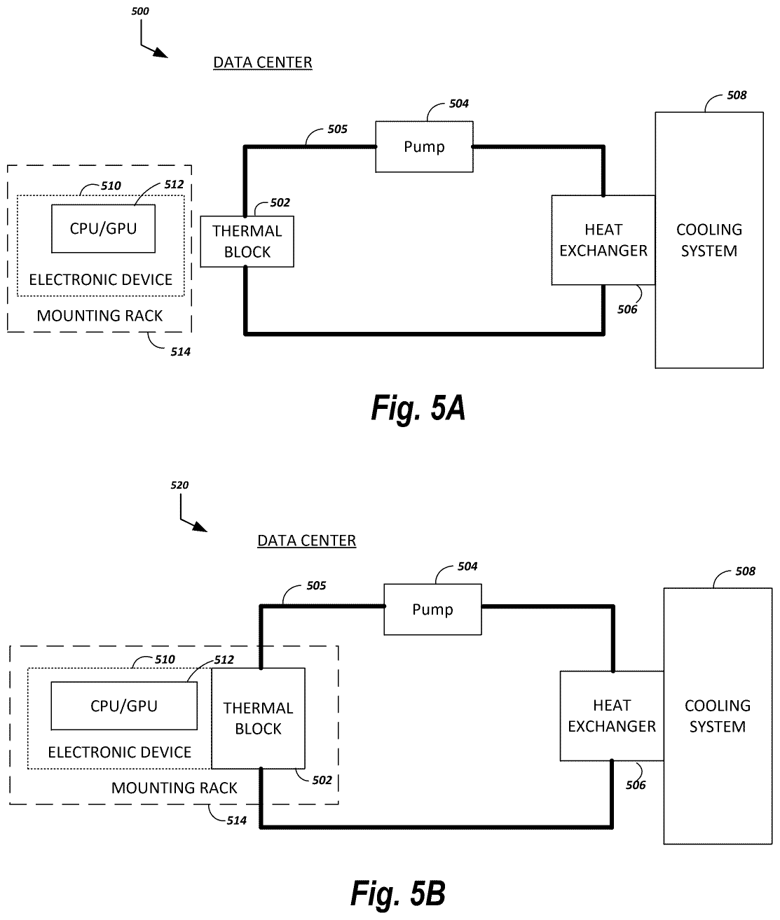

FIG. 5A and FIG. 5B are embodiments of an environment (500 and 520) of an electronic device temperature control system. The environment (500 and 520) can be a data center, which includes multiple electronic devices 510 to be thermally controlled by the temperature control system. Unless indicated otherwise, various features of the temperature control systems and methods described herein with respect to integrated circuit device testers can be included as part of the environments 500 and 520, the details of which may be omitted herein for brevity. In the illustrated embodiments, the electronic devices 510 are configured to be mounted within one or more mounting racks 514, providing houses to the electronic devices 510. In the illustrated embodiments, the data center 500/520 may include pluralities of electronic devices 510 mounted in pluralities of mounting racks 514. The data center 500/520 may further include power supplies to provide power to the electronic devices 510 and other devices. The data center 500/520 may further include cables or other wire/wireless facilities to communicate between the electronic devices 510. In some embodiments, the electronic devices 510 may include one or more servers 512. The server 512 may include at least a processing unit configured to process data and requests. The server 512 may include at least a central processing unit (CPU) or a graphics processing unit (GPU). In some embodiments, the server 512 may include one or more CPUs only. In some embodiments, the server 512 may include a combination of CPUs or GPUs. The server 512 may include one or more network interface cards (NICs), which are configured to interact and communicate with other devices or networks. The server 512 may include one or more random access memory (RAMs) and one or more disk drives, which are configured to store the data. The components within the server 512 are communicated and connected with each other.

The temperature control system may include a closed circulation loop 505, which includes a gas phase heat transfer medium therein to control the temperature of electronic devices 510. In the embodiments of the present disclosure, the gas phase heat transfer medium is not in a liquefied form within the closed circulation loop 505. The gas phase heat transfer medium is pressurized and at a pressure greater than the atmospheric pressure. In some embodiments, the gas phase heat transfer medium is at the pressure of about 2 bar to 30 bar. In some preferred embodiment, the gas phase heat transfer medium is at the pressure of about 7 bar to 10 bar. In some embodiments, the gas phase heat transfer medium comprises clean dry air/compressed dry air. In some embodiments, the gas phase heat transfer medium comprises a composition substantially different from ambient air. In some embodiments, the gas phase heat transfer medium comprises an inert gas. In some embodiments, the gas phase heat transfer medium does not include a hydrocarbon or a hydrofluorocarbon. During the temperature control system's operation, the gas phase heat transfer medium should be at a temperature lower than the electronic device such that a net flow of heat occurs from the electronic devices 510 to the gas phase heat transfer medium. The closed circulation loop 505 may further include a pump 504 used to circulate the gas phase heat transfer medium around the closed circulation loop 505.

The temperature control system may include a thermal block 502 configured to be in thermal communication with a first portion of the closed circulation loop 505 and in further thermal communication with the electronic device 510. In some embodiments, such as those in FIG. 5A, the thermal block may be a radiator, which is not placed within the mounting rack 514. The radiator is configured not to be in physical contact with the electronic devices 510. In some embodiments, the temperature control system may also include a fan or other device close to the radiator to force air across the radiator and carry the cooling power to electronic devices 510. The fan or other device may also be used to blow air across the electronic devices 510 to move heat away from those electronic devices 510.

In some embodiments, such as those in FIG. 5B, the thermal block 502 may correspond to one or more of the thermal heads described herein, e.g., including the thermal head 324 described above with respect to FIG. 3A. In some embodiments, the thermal block may include a network of cooling conduits forming a part of the closed circulation loop 505. In the embodiments as shown in FIG. 5B, the thermal block 502 is configured to be placed within the mounting rack 514, wherein the thermal block 502 is configured to be in physical contact with the electronic devices 510 within the mounting rack 514. Alternatively, the thermal block 502 may be configured to mount directly to some components of the electronic device, which produce the greatest amount of heat. Typically, these components include the CPU and the GPU of the server. Accordingly, one system may have dozens or more individual thermal blocks 502 carrying the gas phase heat transfer medium, with each cooling block directly attaching to a CPU or GPU and carrying heat from those components back to the closed circulation loop 505.

The temperature control system may include a heat exchanger 506 configured to be in thermal communication with a second portion of the closed circulation loop 505. The heat exchanger 506 is in further thermal communication with a cooling system 508 which provides cooling power to the heat exchanger 506 and transfers heat from the closed circulation loop 505 to the cooling system 508. The heat exchanger 506 may include one or more heat transfer plates configured to transfer heat from the closed circulation loop 505 to the cooling system 508. The one or more plates may be made of any thermally conductive material, such as brass, copper, stainless steel, aluminum, thermally conductive ceramic or any other similar material.

The cooling system 508 may use any type of system or device for providing cooling power, such as a cooling system using chilled water or liquid nitrogen, a refrigeration system which includes one or more condensing units, or other system that is configured to provide the proper cooling power to the heat exchanger 506. In some embodiments, the amount of heat transfer medium passed through the closed circulation loop 505 can be modulated in temperature by the cooling system 508, allowing users to select an appropriate temperature for the electronic devices 510 to operate.

Not shown in FIGS. 5A-5B, the temperature control system may further comprise a unidirectional pressure regulator connecting a pressurized gas reservoir to the closed circulation loop 505. The pressurized gas reservoir has the gas phase heat transfer medium at a higher pressure relative to that of the closed circulation loop 505. The unidirectional pressure regulator and pressurized gas reservoir may correspond to the pressure regulator 330 and the gas reservoir 335 as illustrated above in conjunction with FIG. 3A.

### Pressurized Electrical Device Testing System

Generally described, aspects of the present disclosure relate to systems and methods to generate a positive pressure environment (relative to local ambient pressure) within an electrical device testing system 100 as shown in FIG. 1A-1B. The systems and methods described herein can include a positive gas pressure, with a low dew point environment, within an electrical device testing system. This can be achieved through several means, including the use of a continuous sealed outer shell surrounding the external portion of the electrical device testing system. Positive pressure within the testing system may be maintained even when trays are inserted and removed from the system by including an electrically operated door which may open and close to receive and output the trays while maintaining positive pressure within the system. For example, the door may open laterally, and allow a tray housing DUTs to move from the outside to the inside of the system.

The outer shell may be a single piece of material composed of plastic or metal. When the shell is placed around the integrated circuit testing station, the shell can seal the electrical device testing system from an external environment, allowing pressure, humidity and temperature gradients to be established between the ambient environment and an environment within the electrical device testing system.

Electrical device testing systems can require DUTs to be inserted and moved to one or more internal testing stations, while remaining in a secure orientation and position. To accommodate, DUTs can be held within a tray before being loaded into carriers within the system. In some embodiments, a testing station can further include a set of doors, which can open and shut to allow trays to be inserted and removed. To seal an integrated circuit testing station, the door, after a tray has been loaded, can lock into place to isolate the internal environment from the external environment.

### Indexing Carrier System

Generally described, aspects of the present disclosure relate to systems and methods comprising a rotating plate which supports and contains one or more rotating platforms on its upper surface. As the rotating place moves in a circular path within the system, each rotating platform is configured to rotate in a direction counter to the rotating plate. This can be seen in FIG. 1D as described above. The systems and methods described herein can generate rotation and counter rotation so that a carrier mounted on one of the rotating platforms maintains the same orientation within the system and does not rotate as the plate moves in a circular direction. In some embodiments, when the rotating plate is moving in a circular path, the one or more rotating platforms counter-rotate in such a way that the carrier maintains its orientation. The rotating plate and one or more rotating platforms can be rotated an equal number of degrees in opposite directions.

During testing of DUTs within an electrical device testing system, there can be an arrangement of multiple stations, wherein each station corresponds to a different test condition. For example, a first station can equilibrate the DUTs to the internal temperature of the system. Moving the DUTs from one station to another can involve positioning the DUTs on a rotatable platform and rotating the platform so as to align the DUTs with stations positioned within a circular arrangement around a center of the rotating plate.

In one embodiment, the integrated circuit testing station can include five stations spaced apart in a circular arrangement around a rotation plate. The embodiment can also include a mechanism to individually counter-rotate rotating platforms on the rotating plate, with the number of rotating platforms being five, equaling the number of stations. Being that there are five stations and five rotating platforms, moving a carrier clockwise from one station to a next station will require rotating the rotation plate by seventy-two degrees (three-hundred-and-sixty degrees divided by five). Simultaneously, each rotating platform can be configured with gearing to counter-rotate seventy-two degrees in a counterclockwise direction, resulting in each rotating platform facing in a consistent direction before, during, and after rotation of the rotating plate.

A system which includes rotation of a rotating plate and rotating platforms can include a gearing system connected to a central shaft. A gearing system can include a plurality of gears arranged to accommodate a desired system of motion. A gearing system can transfer energy from a mechanical power source to one or more mechanical devices. In some embodiments, the mechanical power source can be an electronic motor. In some embodiments, the one or more mechanical devices can include a rotating plate and one or more rotating platforms.

In some embodiments, a gearing system can be configured to transfer energy to a rotating plate, so as to cause the rotating plate to rotate, while also transferring energy to one or more rotating platforms so as to cause the one or more rotating platforms to rotate in a direction opposite to that of the rotating plate.

### Carrier Stacking Mechanism

Aspects of the present disclosure relate to systems and methods comprising a carrier stacking mechanism of variable height which can be used to stack a plurality of carriers within the soak up and soak down stations within the test system. The systems and methods described herein can include a carrier with a plurality of stacking mechanisms. The stacking mechanisms may include mechanical structures configured to be positioned on a first carrier and lock into a second carrier from below. The stacking mechanisms can be configured to be of adjustable height or can be configured to come in a plurality of heights so that different numbers of carriers are placed within each stack.

DUTs can face numerous operational conditions, from high temperatures, low temperatures, computationally expensive tasks, among others. To ensure DUTs perform adequately under these conditions, the test system is designed to bring the DUTs to a test temperature before testing begins. For example, a stress test may require processors be maintained at 100° C. Other tests may require the DUTs to perform at negative temperatures.

To accommodate this issue, embodiments include a system and method for stacking carriers with a carrier stacking mechanism (hereafter referred to as “stacking mechanism”) so that the carriers with DUTs have sufficient time to come to the appropriate temperature prior to initiating the testing process at a testing station. A stacking mechanism can include a mechanical device which attaches to a carrier and used to secure an additional carrier above and an additional carrier below the stacking mechanism. In this way, a plurality of carriers can be stacked atop one another by loading each carrier from the bottom of a stack. The stacking mechanism can also be of a variable height, wherein the variable height can be achieved through either stacking mechanisms which can be lowered or raised, or a plurality of stacking mechanism with a plurality of heights. Variable heights can correspond to variable amounts of time that the carrier is within the thermal chamber before moving into the testing station. For example, if DUTs are stacked to a relatively large height at a soak up station, then moved laterally to a soak down station, they will spend more time in this process than if the height of the stack included fewer carriers.

A stacking mechanism can include a piece of material, which can be composed of metal or another material, configured to be attached to a carrier connected to a locking mechanism, which can include a latch, positioned on an underside of a carrier. In some embodiments, a carrier can include four stacking mechanisms. For example, a carrier can be roughly rectangularly shaped and can have a stacking mechanism positioned in each of its four corners.

To stack carriers, a method can be applied to a first carrier with a plurality of stacking mechanisms and a second carrier with a plurality of stacking mechanisms, wherein the method can include positioning the second carrier below the first carrier and locking in the stacking mechanisms of the second carrier into locking mechanisms of the first carrier.

### 2D Carrier Tracking

As mentioned above, each station within the test system can test DUTs under varying conditions, the result of which can be used to assign a degree of reliability to the DUTs. For example, if a DUT is exposed to high levels of heat and then fails to achieve a target computational speed when electrical power is applied to the DUT, the DUT can be recorded as having failed its test. Failing a test can correspond to a structural flaw, low structural quality, or other defect in the corresponding DUT. Thus, tracking the DUT's position within the test station and ensuring it is properly identified is essential.

Generally described, aspects of the present disclosure relate to systems and methods of tracking DUTs in test stations. The systems and methods described herein can include: an indicator located on each carrier, wherein the indicator can include visually distinct markers. The indicator may be detected using a vision system to identify each particular carrier, and thus the DUTs within that carrier based on their position in the carrier. The vision system may use a camera or other visual detection device to scan each carrier as it's being loaded with DUTs from a tray and then monitor and track the test results from each DUT in each position within that carrier.

In some embodiments, an indicator can be a bar code, a serial number, or another identifying symbol, image, or device that is identifiable on the surface of the carrier or on the coupon holding each DUT.

In some embodiments, when a DUT is received into a test station, an indicator corresponding to a coupon holding the DUT can be identified and recorded. When the DUT moves from one station to another (within the electrical device testing system), the system can record changes in the DUT's location (corresponding to changes in the identifier attached to the coupon holding the DUT).

In some embodiments, the vision tracker can additionally track a carrier and a coupon's duration within a station, wherein the duration can correspond to how much exposure a DUT has had to low temperatures and high temperatures.

In some embodiments, if a DUT fails a test, the system can record an identifier associated with the DUT. The system can identify a carrier associated with the DUT so that the system can place the DUT which failed a test into a particular output tray or position. For example, if a DUT fails a test, the system can provide to a user an identification number associated with a carrier of A123 and an identification number associated with a coupon of B456. When the user removes carriers from the test station, the user can identify the carrier and coupon and remove the DUT as a failed integrated circuit.

### Contact Cleaning Carrier

Another embodiment is an automatic contactor cleaning system and method. The system and method can include a contactor cleaning carrier being inserted into a test station, moved to one or more stations, and exposed to electrical contacts at the DUT test station so that contacts on the contactor can be cleaned to provide a good electrical connection to the DUTs under test.

Electrical contacts within a contactor are made from conductive materials which are used to mate with DUTs and expose them to electrical current. Electrical contacts are generally made from different types of metal, such as copper, and after being exposed to multiple DUTs, or after an amount of time has passed, the electrical contacts can experience corrosion. This can reduce the electrical conductivity and may result in faulty tests within the system. Over time, the copper can corrode and form copper oxide on the surface of the electrical contacts, wherein copper oxide has a conductivity significantly lower than copper.

Thus, in one embodiment, the testing system includes an automatic contactor cleaning system which includes a specially designed carrier that is placed within the system and configured to contact and clean the contactor connections. This scrubbing contactor cleaner carrier (hereafter referred to as “the cleaning carrier”) can include a carrier holding one or more electrical contact cleaners instead of DUTs. The method can include inserting the cleaning carrier into the testing station and moving the cleaning carrier into the test station. When the cleaning carrier moves into the test station, the station will attempt to establish an electrical connection with the cleaning carrier. While attempting to establish an electrical connection, the station electrical contacts will instead make mechanical contact with the cleaning carrier, whereby the electrical contact can be cleaned by being exposed to an abrasive surface on the cleaning carrier to the contactor connections, and thereby remove corrosion off of the electrical contacts.

### ADDITIONAL EXAMPLES I

1. A system for cooling electronic devices, comprising:
a cooling system comprising a cooling loop and a heat exchange subsystem;
a gaseous heat transfer loop in thermal contact with the heat exchange subsystem, wherein the gaseous heat transfer loop comprises a pressurized gaseous heat transfer medium; and
one or more heat exchangers connected to the gaseous heat transfer loop and mounted adjacent to electronic devices.

2. The system of Embodiment 1, wherein the gaseous heat transfer medium is clean dry air.

3. The system of Embodiment 1, wherein the gaseous heat transfer medium is nitrogen, helium, neon, or argon.

4. The system of Embodiment 1, further comprising a pump configured to move the gaseous heat transfer medium within the gaseous heat transfer loop.

5. The system of Embodiment 1, wherein the cooling system comprises one or more condensing units.

6. The system of Embodiment 1, wherein the electronic devices are computer servers.

7. The system of claim 6, wherein the one or more heat exchangers are in direct thermal contact with the computer servers.

8. The system of Embodiment 6, where the computer servers comprise CPUs and/or GPUs and the one or more heat exchangers are in direct thermal contact with the CPUs and/or GPUs

9. The system of Embodiment 6, wherein the computer servers are mounted into a mounting rack and the one or more heat exchangers are configured to cool the computer servers within the mounting rack.

10. A cooling system comprising:
an electrical device testing system;
a thermal head thermally coupled to the electrical device testing system, wherein the thermal head comprises:
   a cooling system;
   a cooling loop comprising a pressurized gaseous heat transfer medium;
   a cooling block configured to transfer heat from an electrical device to the gaseous heat transfer medium;
   a heating block configured to transfer heat to the thermal head; and
a heat exchanger subsystem configured to transfer heat from the cooling loop to the cooling system.

11. The system of Embodiment 10, wherein pressure within the cooling loop is between two bars and thirty bars.

12. The system of Embodiment 10, wherein the gaseous heat transfer medium is clean dry air.

13. The system of Embodiment 10, wherein the gaseous heat transfer medium is nitrogen, helium, neon, or argon.

14. The system of Embodiment 10, further comprising a pump configured to move the gaseous heat transfer medium within the cooling loop.

15. The system of Embodiment 10, wherein the electrical device is a Ball Grid Array (BGA), Chip Scale Package (CSP), Quad Flat Package (QFP), Quad Flat No-Lead (QFN), Thin Small Outline Package (TSOP), Small Outline Integrated Circuit (SOIC), Plastic Leaded Chip Carrier (PLCC), Ceramic Quad Flat Package (CERQUAD), or Pin Grid Array (PGA) type device.

16. The system of Embodiment 10, wherein the cooling system is a liquid nitrogen cooling system.

17. The system of Embodiment 10, wherein the cooling system comprises one or more condensing units.

18. The system of Embodiment 10, further comprising a controller programmed to read the temperature of the electronic device.

19. The system of Embodiment 18, wherein the controller is configured to activate the heating block if the temperature of the electronic device is below a preset threshold.

20. The system of Embodiment 18, wherein the controller is configured to deactivate the heating block if the temperature of the electronic device is above a preset threshold.

21. The system of Embodiment 10, wherein the thermal head comprises internal channels configured to contain the pressurized gaseous heat transfer medium.

22. The system of Embodiment 10, wherein the cooling block comprises an automatic flow control valve configured to modulate a flow of the gaseous heat transfer medium through the cooling block.

### ADDITIONAL EXAMPLES II

1. A system for cooling electronic devices, comprising:
a cooling system comprising a cooling loop and a heat exchange subsystem;
a gaseous heat transfer loop in thermal contact with the heat exchange subsystem, wherein the gaseous heat transfer loop comprises a pressurized gaseous heat transfer medium; and
one or more heat exchangers connected to the gaseous heat transfer loop and mounted adjacent to electronic devices.

2. The system of Embodiment 1, wherein the gaseous heat transfer medium is clean dry air.

3. The system of Embodiment 1, wherein the gaseous heat transfer medium is nitrogen, helium, neon, or argon.

4. The system of Embodiment 1, further comprising a pump configured to move the gaseous heat transfer medium within the gaseous heat transfer loop.

5. The system of Embodiment 1, wherein the cooling system comprises one or more condensing units.

6. The system of Embodiment 1, wherein the electronic devices are computer servers.

7. The system of Embodiment 6, wherein the one or more heat exchangers are in direct thermal contact with the computer servers.

8. The system of Embodiment 6, where the computer servers comprise CPUs and/or GPUs and the one or more heat exchangers are in direct thermal contact with the CPUs and/or GPUs

9. The system of Embodiment 6, wherein the computer servers are mounted into a mounting rack and the one or more heat exchangers are configured to cool the computer servers within the mounting rack.

10. A cooling system comprising:
an electrical device testing system;
a thermal head thermally coupled to the electrical device testing system, wherein the thermal head comprises:
   a cooling system;
   a cooling loop comprising a pressurized gaseous heat transfer medium;
   a cooling block configured to transfer heat from an electrical device to the gaseous heat transfer medium;
   a heating block configured to transfer heat to the thermal head; and
a heat exchanger subsystem configured to transfer heat from the cooling loop to the cooling system.

11. The system of Embodiment 10, wherein pressure within the cooling loop is between two bars and thirty bars.

12. The system of Embodiment 10, wherein the gaseous heat transfer medium is clean dry air.

13. The system of Embodiment 10, wherein the gaseous heat transfer medium is nitrogen, helium, neon, or argon.

14. The system of Embodiment 10, further comprising a pump configured to move the gaseous heat transfer medium within the cooling loop.

15. The system of Embodiment 10, wherein the electrical device is a Ball Grid Array (BGA), Chip Scale Package (CSP), Quad Flat Package (QFP), Quad Flat No-Lead (QFN), Thin Small Outline Package (TSOP), Small Outline Integrated Circuit (SOIC), Plastic Leaded Chip Carrier (PLCC), Ceramic Quad Flat Package (CERQUAD), or Pin Grid Array (PGA) type device.

16. The system of Embodiment 10, wherein the cooling system is a liquid nitrogen cooling system.

17. The system of Embodiment 10, wherein the cooling system comprises one or more condensing units.

18. The system of Embodiment 10, further comprising a controller programmed to read the temperature of the electronic device.

19. The system of Embodiment 18, wherein the controller is configured to activate the heating block if the temperature of the electronic device is below a preset threshold.

20. The system of Embodiment 18, wherein the controller is configured to deactivate the heating block if the temperature of the electronic device is above a preset threshold.

21. The system of Embodiment 10, wherein the thermal head comprises internal channels configured to contain the pressurized gaseous heat transfer medium.

22. The system of Embodiment 10, wherein the cooling block comprises an automatic flow control valve configured to modulate a flow of the gaseous heat transfer medium through the cooling block.

### Additional Considerations

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

In addition, unless otherwise specified, none of the steps of the methods of the present disclosure are confined to any particular order of performance. Modifications of the disclosed examples incorporating the spirit and substance of the disclosure may occur to persons skilled in the art and such modifications are within the scope of the present disclosure. Furthermore, all references cited herein are incorporated by reference in their entirety.

While the methods and devices described herein may be susceptible to various modifications and alternative forms, specific examples thereof have been shown in the drawings and are herein described in detail. It should be understood, however, that the invention is not to be limited to the particular forms or methods disclosed, but, to the contrary, the invention is to cover all modifications, equivalents, and alternatives falling within the spirit and scope of the various examples described and the appended claims. Further, the disclosure herein of any particular feature, aspect, method, property, characteristic, quality, attribute, element, or the like in connection with an example can be used in all other examples set forth herein. Any methods disclosed herein need not be performed in the order recited. Depending on the example, one or more acts, events, or functions of any of the algorithms, methods, or processes described herein can be performed in a different sequence, can be added, merged, or left out altogether (e.g., not all described acts or events are necessary for the practice of the method). In some examples, acts or events can be performed concurrently. Further, no element, feature, block, or step, or group of elements, features, blocks, or steps, are necessary or indispensable to each example. Additionally, all possible combinations, subcombinations, and rearrangements of systems, methods, features, elements, modules, blocks, and so forth are within the scope of this disclosure. The use of sequential, or time-ordered language, such as “then,” “next,” “after,” “subsequently,” and the like, unless specifically stated otherwise, or otherwise understood within the context as used, is generally intended to facilitate the flow of the text and is not intended to limit the sequence of operations performed. Thus, some examples may be performed using the sequence of operations described herein, while other examples may be performed following a different sequence of operations.

The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 1 V” includes “1 V.” Numbers not preceded by a term such as “about” or “approximately” may be understood to based on the circumstances to be as accurate as reasonably possible under the circumstances, for example ±5%, +10%, +15%, etc. For example, “1 V” includes “0.9-1.1 V.” Phrases preceded by a term such as “substantially” include the recited phrase and should be interpreted based on the circumstances (e.g., as much as reasonably possible under the circumstances). For example, “substantially perpendicular” includes “perpendicular.” Unless stated otherwise, all measurements are at standard conditions including temperature and pressure. The phrase “at least one of” is intended to require at least one item from the subsequent listing, not one type of each item from each item in the subsequent listing. For example, “at least one of A, B, and C” can include A, B, C, A and B, A and C, B and C, or A, B, and C.

1. A system for controlling temperature of an electronic device under test (DUT), the system comprising:
a closed circulation loop having pressurized therein a gas phase heat transfer medium at a pressure greater than an atmospheric pressure;
a plunger configured to be in thermal communication with a first portion of the closed circulation loop and in further thermal communication with the DUT; and
a heat exchanger configured to be in thermal communication with a second portion of the closed circulation loop.

2. The system of claim 1, wherein the heat exchanger is in further thermal communication with a cooling system for transferring heat from the second portion of the closed circulation loop thereto.

3. The system of claim 1, wherein the plunger is configured to be in physical contact with the DUT.

4. The system of claim 1, wherein in operation, the gas phase heat transfer medium is configured to be at a temperature lower than the DUT such that a net flow of heat occurs from the DUT to the gas phase heat transfer medium.

5. The system of claim 1, wherein the gas phase heat transfer medium is at the pressure of about 7 bar to 10 bar.

6. The system of claim 1, wherein the gas phase heat transfer medium comprises compressed dry air.

7. The system of claim 1, wherein the gas phase heat transfer medium comprises a composition substantially different from ambient air.

8. (canceled)

9. The system of claim 1, wherein the gas phase heat transfer medium does not include a hydrocarbon or a hydrofluorocarbon.

10. (canceled)

11. The system of claim 1, further comprising a unidirectional pressure regulator connecting a pressurized gas reservoir to the closed circulation loop, the pressurized gas reservoir having the gas phase heat transfer medium at a higher pressure relative to that of the closed circulation loop.

12. The system of claim 1, wherein the plunger comprises a network of cooling conduits forming a part of the closed circulation loop.

13. The system of claim 12, wherein the plunger further comprises a heating block, configured to be closer to the DUT than the network of cooling conduits.

14. (canceled)

15. The system of claim 1, wherein the closed circulation loop comprises a pump configured to circulate the gas phase heat transfer medium around the closed circulation loop.

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. An apparatus for testing an electronic device under test (DUT), the apparatus comprising:
a testing station configured to receive the DUT and perform electrical testing therein using a contactor;
the contactor configured to electrically and physically contact with the DUT at a first side of the DUT for sending and receiving testing signals;
a plunger configured to be in physical contact and thermal communication with the DUT at a second side for controlling temperature of the DUT during testing; and
a closed circulation loop having pressurized therein a gas phase heat transfer medium at a pressure greater than an atmospheric pressure in thermal communication with the plunger.

34. The apparatus of claim 33, wherein the plunger is configured to be in thermal communication with a first portion of the closed circulation loop, and wherein the apparatus further comprises a heat exchanger in thermal communication with a second portion of the closed circulation loop.

35. The apparatus of claim 34, wherein the heat exchanger is in further thermal communication with a cooling system for transferring heat from the second portion of the closed circulation loop thereto.

36. The apparatus of claim 33, wherein in operation, the gas phase heat transfer medium is configured to be at a temperature lower than the DUT such that a net flow of heat occurs from the DUT to the gas phase heat transfer medium.

37. The apparatus of claim 33, wherein the gas phase heat transfer medium is at the pressure of about 7 bar to 10 bar.

38. The apparatus of claim 33, wherein the gas phase heat transfer medium comprises a composition substantially different from ambient air.

39. (canceled)

40. (canceled)

41. (canceled)

42. The apparatus of claim 33, wherein the gas phase heat transfer medium comprises compressed dry air.

43. The apparatus of claim 33, wherein the apparatus comprises a plurality of stations including the testing station, wherein the carrier assembly rotates through the plurality of stations on a carrier retainer disk without being removed from the carrier retainer disk.
